(19) United States
(12) Patent Application Publication
(10) Pub. No.: US 2022/0320272 A1
(43) Pub. Date: Oct. 6, 2022

(54) SEMICONDUCTOR DEVICE AND METHOD FOR MANUFACTURING SEMICONDUCTOR DEVICE

(71) Applicant: SONY SEMICONDUCTOR SOLUTIONS CORPORATION, KANAGAWA (JP)

(72) Inventor: KOJI NAGATOMO, KUMAMOTO (JP)

(21) Appl. No.: 17/596,936

(22) PCT Filed: Jun. 25, 2020
(86) PCT No.: PCT/JP2020/025102

§ 371 Date: Dec. 22, 2021

(30) Foreign Application Priority Data
Jul. 3, 2019 (JP) 2019-124243

(51) Int. Cl. H01L 29/06; H01L 29/78; H01L 29/80; H01L 29/43

(52) U.S. Cl. CPC H01L 29/0646; H01L 29/783; H01L 29/80; H01L 29/432

(57) ABSTRACT

The performance of a transistor is improved. The semiconductor device according to the embodiment includes: an insulating film (12) that separates an n-type transistor formation region (Tr1) and a p-type transistor formation region (Tr2) from each other, in which each of the n-type transistor formation region and the p-type transistor formation region includes a gate electrode (13) formed in a first direction on a semiconductor substrate (11), and source/drain regions (22) formed on both sides of the gate electrode in a second direction different from the first direction, and a distance from an interface between the insulating film and the source/drain regions to an end of the gate electrode in the second direction is different between the n-type transistor formation region and the p-type transistor formation region.

### FIELD

The present disclosure relates to a semiconductor device and a method for manufacturing the semiconductor device.

### BACKGROUND

In recent years, high integration, high speed, and low power consumption of semiconductor integrated circuits have progressed, and there is an increasing demand for performance improvement for individual transistors. In addition, with the progress of the generation of transistors, not only transistors having a two-dimensional structure (planar type) but also transistors having a three-dimensional structure have been put into practical use.

### CITATION LIST

### Patent Literature

Patent Literature 1: JP 2010-141102 A

Patent Literature 2: JP 2010-192588 A

### SUMMARY

### Technical Problem

In both the two-dimensional transistor and the three-dimensional transistor, in order to improve the performance of the transistor, for example, it is necessary to improve carrier mobility and to suppress variations in characteristics of the transistor.

Therefore, the present disclosure proposes a semiconductor device and a method for manufacturing the semiconductor device capable of improving the performance of the transistor.

### Solution to Problem

To solve the above-described problem, a semiconductor device according to one aspect of the present disclosure comprises: an insulating film that separates an n-type transistor formation region and a p-type transistor formation region from each other, wherein each of the n-type transistor formation region and the p-type transistor formation region includes a gate electrode formed in a first direction on a semiconductor substrate, and source/drain regions formed on both sides of the gate electrode in a second direction different from the first direction, and a distance from an interface between the insulating film and the source/drain regions to an end of the gate electrode in the second direction is different between the n-type transistor formation region and the p-type transistor formation region.

### BRIEF DESCRIPTION OF DRAWINGS

FIG. 1 is a view illustrating a configuration example of a semiconductor device according to a first embodiment.

FIG. 2A is a view illustrating a carrier mobility characteristic (part 1).

FIG. 2B is a view illustrating a carrier mobility characteristic (part 2).

FIG. 3A is a view illustrating a planar shape of the semiconductor device according to the first embodiment.

FIG. 3B is a view illustrating another planar shape of the semiconductor device according to the first embodiment.

FIG. 4A is a plan view illustrating a method for manufacturing the semiconductor device according to the first embodiment (part 1).

FIG. 4B is a cross-sectional view illustrating the method for manufacturing the semiconductor device according to the first embodiment (part 1).

FIG. 5A is a plan view illustrating another method for manufacturing the semiconductor device according to the first embodiment (part 1).

FIG. 5B is a cross-sectional view illustrating another method for manufacturing the semiconductor device according to the first embodiment (part 1).

FIG. 6A is a plan view illustrating the method for manufacturing the semiconductor device according to the first embodiment (part 2).

FIG. 6B is a cross-sectional view illustrating the method for manufacturing the semiconductor device according to the first embodiment (part 2).

FIG. 7A is a plan view illustrating the method for manufacturing the semiconductor device according to the first embodiment (part 3).

FIG. 7B is a cross-sectional view illustrating the method for manufacturing the semiconductor device according to the first embodiment (part 3).

FIG. 8A is a plan view illustrating the method for manufacturing the semiconductor device according to the first embodiment (part 4).

FIG. 8B is a cross-sectional view illustrating the method for manufacturing the semiconductor device according to the first embodiment (part 4).

FIG. 9A is a plan view illustrating the method for manufacturing the semiconductor device according to the first embodiment (part 5).

FIG. 9B is a cross-sectional view illustrating the method for manufacturing the semiconductor device according to the first embodiment (part 5).

FIG. 10A is a plan view illustrating the method for manufacturing the semiconductor device according to the first embodiment (part 6).

FIG. 10B is a cross-sectional view illustrating the method for manufacturing the semiconductor device according to the first embodiment (part 6).

FIG. 11A is a view illustrating an example of a planar shape of a semiconductor device according to a first example of a second embodiment.

FIG. 11B is a view illustrating an example of another planar shape of the semiconductor device according to the first example of the second embodiment.

FIG. 12A is a view illustrating an example of a planar shape of a semiconductor device according to a second example of the second embodiment.

FIG. 12B is a view illustrating an example of another planar shape of the semiconductor device according to the second example of the second embodiment.

FIG. 13A is a view illustrating a configuration example of a semiconductor device according to a first example of a third embodiment.

FIG. 13B is a cross-sectional view illustrating a cross-sectional shape of the semiconductor device according to the first example of the third embodiment.

FIG. 14A is a plan view illustrating a planar shape of the semiconductor device according to the first example of the third embodiment.

FIG. 14B is a plan view illustrating another planar shape of the semiconductor device according to the first example of the third embodiment.

FIG. 15A is a view illustrating a configuration example of a semiconductor device according to a second example of the third embodiment.

FIG. 15B is a cross-sectional view illustrating a cross-sectional shape of the semiconductor device according to the second example of the third embodiment.

FIG. 16A is a plan view illustrating a planar shape of the semiconductor device according to the second example of the third embodiment.

FIG. 16B is a plan view illustrating another planar shape of the semiconductor device according to the second example of the third embodiment.

FIG. 17A is a view illustrating a configuration example of a semiconductor device according to a third example of the third embodiment.

FIG. 17B is a cross-sectional view illustrating a cross-sectional shape of the semiconductor device according to the third example of the third embodiment.

FIG. 18A is a cross-sectional view illustrating an example of a cross-sectional shape of a semiconductor device according to a fourth embodiment.

FIG. 18B is a cross-sectional view illustrating an example of another cross-sectional shape of the semiconductor device according to the fourth embodiment.

FIG. 19A is a cross-sectional view illustrating an example of a cross-sectional shape of a semiconductor device according to a fifth embodiment.

FIG. 19B is a cross-sectional view illustrating an example of another cross-sectional shape of the semiconductor device according to the fifth embodiment.

### DESCRIPTION OF EMBODIMENTS

Hereinafter, embodiments of the present disclosure will be described in detail with reference to the drawings. In each of the following embodiments, the same parts are denoted by the same reference numerals, and redundant description will be omitted.

In addition, the present disclosure will be described according to the following item order.

1. First Embodiment

1.1 Configuration example of semiconductor device according to first embodiment

1.2 Configuration example of transistor according to first embodiment

1.3 Mobility characteristics of carrier

1.4 Planar shape of semiconductor device according to first embodiment

1.5 Method for manufacturing semiconductor device according to first embodiment

1.6 Action and effect

2. Second Embodiment

2.1 Planar shape of semiconductor device according to second embodiment

2.2 Action and effect

3. Third Embodiment

3.1 Configuration example of semiconductor device according to first example of third embodiment

3.2 Configuration example of transistor according to first example of third embodiment

3.3 Planar shape of semiconductor device according to first example of third embodiment

3.4 Configuration example of semiconductor device according to second example of third embodiment

3.5 Configuration example of semiconductor device according to third example of third embodiment

3.6 Action and effect

4. Fourth Embodiment

4.1 Cross-sectional shape of semiconductor device according to fourth embodiment

4.2 Action and effect

5. Fifth Embodiment

5.1 Configuration example of semiconductor device according to fifth embodiment

5.2 Action and effect

6. Others

### 1. First Embodiment

1.1 Configuration Example of Semiconductor Device According to First Embodiment

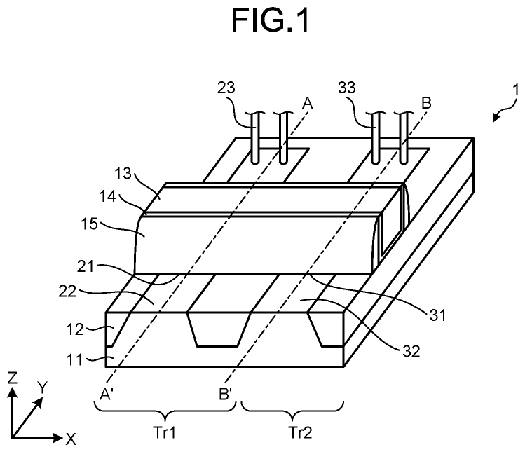

FIG. 1 is a view illustrating a configuration example of a semiconductor device according to a first embodiment.

As illustrated in FIG. 1, a semiconductor device 1 includes a semiconductor substrate 11, an insulating film 12, an n-type transistor formation region Tr1, and a p-type transistor formation region Tr2.

For the semiconductor substrate 11, for example, a silicon substrate is used. The insulating film 12 electrically insulates the n-type transistor formation region Tr1 and the p-type transistor formation region Tr2. The insulating film 12 may be an element isolation film that isolates the n-type transistor formation region Tr1 and the p-type transistor formation region Tr2, or may be formed in a shallow trench isolation (STI) structure formed of an oxide film.

1.2 Configuration Example of Transistor According to First Embodiment

The n-type transistor formation region Tr1 includes an n-type transistor including a gate electrode 13, a gate insulating film 14, a sidewall insulating film 15, and a pair of source/drain regions 22. A region under the gate electrode 13 in the semiconductor substrate 11 and sandwiched between the pair of source/drain regions 22 functions as a channel formation region 21 in which a channel is formed during driving. The n-type transistor is electrically connected to wiring or a circuit element (not illustrated) via a contact electrode 23 in contact with the source/drain regions 22.

Similarly, the p-type transistor formation region Tr2 includes a p-type transistor including the gate electrode 13, the gate insulating film 14, the sidewall insulating film 15, and a pair of source/drain regions 32. A region under the gate electrode 13 in the semiconductor substrate 11 and sandwiched between the pair of source/drain regions 32 functions as a channel formation region 31 in which a channel is formed during driving. The p-type transistor is electrically connected to wiring or a circuit element (not illustrated) via a contact electrode 33 in contact with the source/drain regions 32.

Although FIG. 1 illustrates a case where the gate structure including the gate electrode 13, the gate insulating film 14, and the sidewall insulating film 15 is shared by the n-type transistor and the p-type transistor, the present disclosure is not limited to such a structure, and different gate structures may be provided in the n-type transistor and the p-type transistor.

A p-type well region (not illustrated) into which a p-type impurity is introduced is formed in the semiconductor substrate 11 of the n-type transistor formation region Tr1, and an n-type well region (not illustrated) into which an n-type impurity is introduced is formed in the semiconductor substrate 11 of the p-type transistor formation region Tr2.

The channel formation region 21 is formed by introducing a p-type impurity into the p-type well region, and the channel formation region 31 is formed by introducing an n-type impurity into the n-type well region.

The gate electrode 13 is formed in the n-type transistor formation region Tr1 and the p-type transistor formation region Tr2 in an X direction (gate width direction). Note that the X direction (gate width direction) corresponds to, for example, a first direction described in the claims. For the gate electrode 13, for example, a metal compound layer or a metal layer is used. As the metal layer, tungsten (W), titanium (Ti), titanium nitride (TiN), hafnium (Hf), hafnium silicide (HfSi), ruthenium (Ru), iridium (Ir), cobalt (Co), and the like can be selected. The metal layer may be a single-layer film, or may have a stacked structure in which a plurality of metal films is stacked to adjust the threshold voltage.

The gate insulating film 14 is formed of, for example, a high dielectric constant (high-k) insulating film having a thickness of 2 nm (nanometer) to 3 nm. As the high-k material, hafnium oxide (HfO₂), hafnium oxide silicide (HfSiO), tantalum oxide (Ta₂O₅), aluminum hafnium oxide (HfAlOₓ), and the like can be used. Alternatively, the gate insulating film 14 may be formed by oxidizing the surface of the semiconductor substrate 11.

The sidewall insulating film 15 is formed on the sidewall of the gate insulating film 14, and is formed of a silicon oxide film (SiO₂), a silicon nitride film (SiN), and the like.

The pair of source/drain regions 22 is formed in a pair of regions that are upper layer portions on the element formation surface side in the semiconductor substrate 11 and sandwich a region under the gate electrode 13 from a Y direction (gate length direction). Similarly, the pair of source/drain regions 32 is formed in a pair of regions that are upper layer portions on the element formation surface side in the semiconductor substrate 11 and sandwich the region under the gate electrode 13 from the Y direction (gate length direction). Note that the Y direction (gate length direction) corresponds to, for example, a second direction described in the claims.

In addition, a low resistance layer may be formed on the surfaces of the source/drain regions 22 and 32. The low resistance layer is a layer for reducing the resistance between the source/drain regions 22 and 32 and the contact electrodes 23 and 33, and is formed of, for example, cobalt (Co), nickel (Ni), platinum (Pt), a compound of them, and the like. Examples of the compound include metal silicide of these metals.

1.3 Mobility Characteristics of Carrier

In order to improve the carrier mobility (also referred to as channel mobility) of the channel formation regions 21 and 31, it is desirable that a tensile stress in the Y direction (gate length direction) be applied to the channel formation region 21 of the n-type transistor formation region Tr1, and a compressive stress in the Y direction (gate length direction) be applied to the channel formation region 31 of the p-type transistor formation region Tr2.

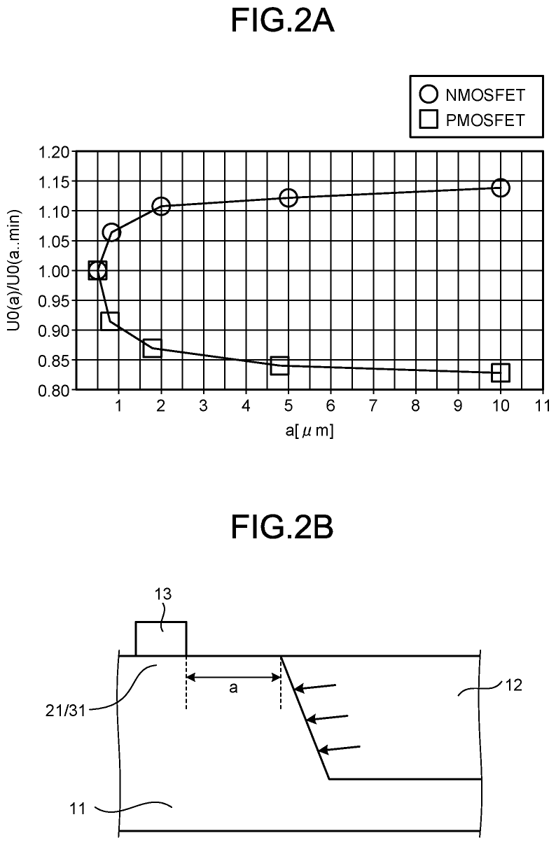

FIG. 2A illustrates carrier mobility of the n-type transistor formation region Tr1 and the p-type transistor formation region Tr2 in a case where the insulating film 12 applies compressive stress in the Y direction (gate length direction) to the channel formation regions 21 and 31.

a (μm) indicates a distance from the interface between the insulating film 12 and the source/drain regions 22/32 to the end of the gate electrode 13 in the Y direction (gate length direction). U0 (a) indicates the carrier mobility in a case where the distance from the interface between the insulating film 12 and the source/drain regions 22/32 to the end of the gate electrode 13 is a μm. U0 (a_min) indicates the carrier mobility in a case where the minimum distance from the interface between the insulating film 12 and the source/drain regions 22/32 to the end of the gate electrode 13 is a_min (μm). The minimum distance in this case is, for example, 0.4 (=a_min) μm.

As illustrated in FIG. 2B, the carrier mobility is enhanced by applying compressive stress in the Y direction (gate length direction) to the channel formation region of the p-type transistor. On the other hand, regarding the n-type transistor, the carrier mobility is enhanced by applying tensile stress in the Y direction (gate length direction) to the channel formation region.

Therefore, for example, by using a material having a thermal expansion coefficient smaller than the thermal expansion coefficient of the semiconductor substrate 11 for the material of the insulating film 12, it is possible to apply a compressive stress to a region adjacent to the insulating film 12 or a region sandwiched between two or more insulating films 12 in the semiconductor substrate 11. This is because the stress (hereinafter, simply referred to as compressive stress) in the direction of compressing the channel formation regions 21 and 31 in the semiconductor substrate 11 remains in the semiconductor device 1 as a result of application of the force of expansion of the insulating film 12 to the semiconductor substrate 11 in the film formation process of the insulating film 12 or the subsequent high-temperature heat treatment process.

On the other hand, in a case where a material having a thermal expansion coefficient larger than the thermal expansion coefficient of the semiconductor substrate 11 is used for the material of the insulating film 12, it is possible to apply a tensile stress to the region adjacent to the insulating film 12 or a region sandwiched between two insulating films 12 in the semiconductor substrate 11. This is because the stress (hereinafter, simply referred to as tensile stress) in the direction of pulling the channel formation regions 21 and 31 in the semiconductor substrate 11 that is opposite to the above remains in the semiconductor device 1 as a result of application of the force of expansion of the semiconductor substrate 11 to the insulating film 12 in the film formation process of the insulating film 12 or the subsequent high-temperature heat treatment process.

Note that the source/drain regions 22 and 32 and the channel formation regions 21 and 31 may be included in the region adjacent to the insulating film 12 or the region sandwiched by two or more insulating films 12 in the semiconductor substrate 11. In the following description, the region adjacent to the insulating film 12 or the region sandwiched between two or more insulating films 12 in the semiconductor substrate 11 is referred to as a transistor formation region.

The compressive stress and the tensile stress in the Y direction as described above depend on, for example, the distance (hereinafter, this is referred to as a distance a) from the interface between the insulating film 12 and the source/drain regions 22/32 to the end of the gate electrode 13. For example, in a case where a material having a thermal expansion coefficient smaller than the thermal expansion coefficient of the semiconductor substrate 11 is used for the material of the insulating film 12, the compressive stress acting on the channel formation region 21/31 can be increased as the distance a is shortened, in other words, as the interface between the insulating film 12 and the source/drain regions 22/32 approaches the channel formation region 21/31. Similarly, for example, in a case where a material having a thermal expansion coefficient larger than the thermal expansion coefficient of the semiconductor substrate 11 is used for the material of the insulating film 12, the tensile stress acting on the channel formation region 21/31 can be increased as the distance a is shortened, in other words, as the interface between the insulating film 12 and the source/drain regions 22/32 approaches the channel formation region 21/31.

Therefore, in the present embodiment, by providing a difference in the distance a from the interface between the insulating film 12 and the source/drain regions 22/32 to the end of the gate electrode 13 between the n-type transistor formation region Tr1 and the p-type transistor formation region Tr2, a difference is provided in compressive stress or tensile stress acting on the channel formation regions 21 and 31.

For example, in a case where a material having a thermal expansion coefficient smaller than the thermal expansion coefficient of the semiconductor substrate 11 is used for the material of the insulating film 12, by decreasing the distance a in the p-type transistor formation region Tr2 and increasing the distance a in the n-type transistor formation region Tr1, it is possible to suppress a reduction in the carrier mobility of the n-type transistor while increasing the carrier mobility of the p-type transistor. Similarly, in a case where a material having a thermal expansion coefficient larger than the thermal expansion coefficient of the semiconductor substrate 11 is used for the material of the insulating film 12, by decreasing the distance a in the n-type transistor formation region Tr1 and increasing the distance a in the p-type transistor formation region Tr2, it is possible to suppress a reduction in the carrier mobility of the p-type transistor while increasing the carrier mobility of the n-type transistor.

Note that a material having a thermal expansion coefficient smaller than the thermal expansion coefficient of the semiconductor substrate 11 may be used for the material of the insulating film 12 around the p-type transistor formation region Tr2, and a material having a thermal expansion coefficient larger than the thermal expansion coefficient of the semiconductor substrate 11 may be used for the material of the insulating film 12 around the n-type transistor formation region Tr1. In that case, in both the p-type transistor formation region Tr2 and the n-type transistor formation region Tr1, by making the distance a from the interface between the insulating film 12 and the source/drain regions 22/32 to the end of the gate electrode 13 close, the carrier mobility of both the p-type transistor and the n-type transistor can be increased.

Further, the source/drain regions 22 and 32 may be configured to apply a compressive stress or a tensile stress to the channel formation regions 21 and 31. For example, in a case where silicon carbide (SiC), silicon phosphide (SiP), and the like grown by epitaxial growth is used for the source/drain regions 22 of the n-type transistor formation region Tr1, a tensile stress in the Y direction (gate length direction) can be applied to the channel formation region 21. In addition, for example, in a case where silicon germanium (SiGe) and the like grown by epitaxial growth is used in the source/drain regions 32 of the p-type transistor formation region Tr2, a compressive stress in the Y direction (gate length direction) can be applied to the channel formation region 31.

1.4 Planar Shape of Semiconductor Device According to First Embodiment

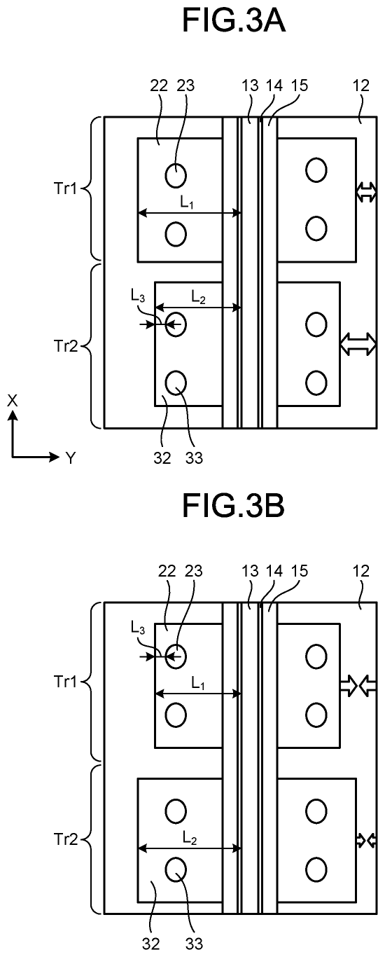

FIGS. 3A and 3B illustrate a planar shape on an X-Y plane in FIG. 1. The insulating film 12 is formed in a manner that distances L₁ and L₂ from the interface between the insulating film 12 and the source/drain regions 22 and 32 to the end of the gate electrode 13 in the Y direction (gate length direction) are different between the n-type transistor formation region Tr1 and the p-type transistor formation region Tr2.

FIG. 3A illustrates a case where the insulating film 12 applies compressive stress to the channel formation regions 21 and 31. In the distances L₁ and L₂ from the interface between the insulating film 12 and the source/drain regions 22 and 32 to the end of the gate electrode 13, the p-type transistor formation region Tr2 is shorter than the n-type transistor formation region Tr1 (L₁>L₂). This makes it possible to increase the compressive stress acting on the channel formation region 31 of the p-type transistor formation region Tr2 from the insulating film 12 and/or decrease the compressive stress acting on the channel formation region 21 of the n-type transistor formation region Tr1 from the insulating film 12 in the Y direction (gate length direction). As a result, the carrier mobility of the channel formation region 31 of the p-type transistor formation region Tr2 can be improved, and/or a decrease in the carrier mobility of the channel formation region 21 of the n-type transistor formation region Tr1 can be suppressed.

FIG. 3B illustrates a case where the insulating film 12 applies tensile stress to the channel formation regions 21 and 31. In the distances L₁ and L₂ from the interface between the insulating film 12 and the source/drain regions 22 and 32 to the end of the gate electrode 13, the n-type transistor formation region Tr1 is shorter than the p-type transistor formation region Tr2 (L₁<L₂). This makes it possible to increase the tensile stress acting on the channel formation region 31 of the n-type transistor formation region Tr1 from the insulating film 12 and/or decrease the tensile stress acting on the channel formation region 31 of the p-type transistor formation region Tr2 from the insulating film 12 in the Y direction (gate length direction). As a result, the carrier mobility of the channel formation region 21 of the n-type transistor formation region Tr1 can be improved, and/or a decrease in the carrier mobility of the channel formation region 31 of the p-type transistor formation region Tr2 can be suppressed.

In the n-type transistor formation region Tr1 and the p-type transistor formation region Tr2, the difference between the distances L₁ and L₂ from the interface between the insulating film 12 and the source/drain regions 22 and 32 to the end of the gate electrode 13 is desirably large. By adjusting the difference between the distances L₁ and L₂, it is possible to improve or suppress a decrease in the carrier mobility of the channel formation region 21 of the n-type transistor formation region Tr1 and to suppress a decrease in or improve the carrier mobility of the channel formation region 31 of the p-type transistor formation region Tr2 in a well-balanced manner.

A distance L₃ from the ends of the contact electrodes 23 and 33 to the interfaces between the insulating film 12 and the source/drain regions 22 and 32 is desirably equal to or larger than a margin required from the process accuracy. As a result, an increase in contact resistance and a connection failure can be suppressed, and the performance of the transistor can be improved.

However, if the distance L₁ is too large, the adjacent transistors in the Y direction are too close to each other, increasing the possibility of generating a leakage current between the adjacent transistors. Therefore, the distance L₁ is desirably set to a large value within a range in which element isolation between adjacent transistors does not fail.

On the other hand, if the distance L₂ is too short, defects such as an increase in resistance between the contact electrodes 23 and 33 and the source/drain regions 22 and 32 and occurrence of a connection failure may occur. Therefore, the distance L₂ is desirably set in a manner that the distance L₃ takes a value larger than 0 in such a way that the contact electrodes 23 and 33 do not cause a connection failure. However, the distance L₂ is preferably as small as possible as long as the distance L₂ is within a range that does not cause a connection failure.

In addition, in the present embodiment, in both the source/drain regions 22 and 32, the distance from the interface between the insulating film 12 and the source/drain regions 22 and 32 to the end of the gate electrode 13 is formed to be different between the n-type transistor formation region Tr1 and the p-type transistor formation region Tr2, but the present disclosure is not limited to this. In any one of the source/drain regions 22 and 32, the distance from the interface between the insulating film 12 and the source/drain regions 22 and 32 to the end of the gate electrode 13 is formed to be different between the n-type transistor formation region Tr1 and the p-type transistor formation region Tr2. That is, the distance from the interface between one of the source region and the drain region of the source/drain regions 22 and 32 and the insulating film 12 to the end of the gate electrode 13 may be different between the n-type transistor formation region Tr1 and the p-type transistor formation region Tr2.

Note that the effects described in the present embodiment are merely examples and are not limited, and other effects may be provided. In addition, in the present embodiment, a single gate structure including a single gate electrode applied to an inverter and the like has been described, but the present disclosure is not limited to this, and a multi-gate structure including a plurality of gate electrodes can also be applied.

1.5 Method for Manufacturing Semiconductor Device According to First Embodiment

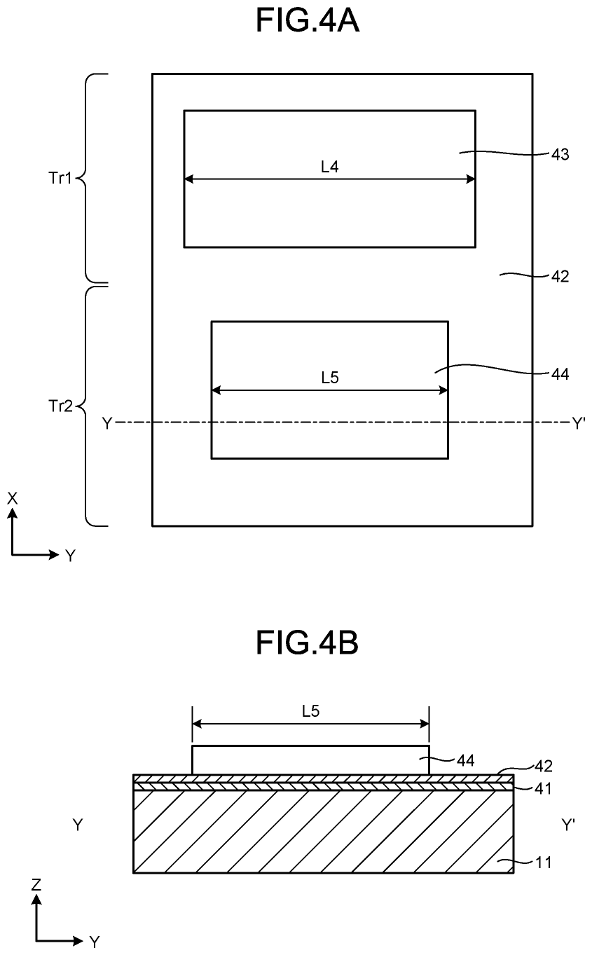

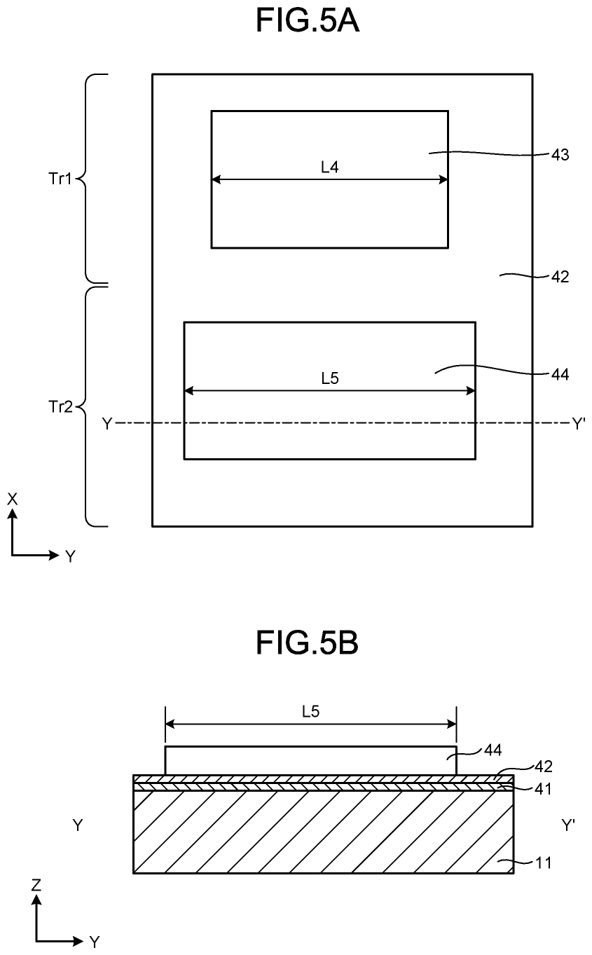

FIGS. 4A to 10B illustrate a manufacturing process according to the first embodiment. FIGS. 4A, 5A, 6A, 7A, 8A, 9A, and 10A illustrate a planar shape on the X-Y plane of FIG. 1, and FIGS. 4B, 5B, 6B, 7B, 8B, 9B, and 10B are cross-sectional views illustrating a cross-sectional shape on a Y-Y′ plane illustrated in FIGS. 4A, 5A, 6A, 7A, 8A, 9A, and 10A. Note that FIGS. 4A and 4B illustrate a process in a case where the insulating film 12 applies compressive stress in the Y direction (gate length direction) to the channel formation regions 21 and 31, and FIGS. 5A and 5B illustrate a process in a case where the insulating film 12 applies tensile stress in the Y direction (gate length direction) to the channel formation regions 21 and 31.

As illustrated in FIGS. 4B and 5B, a silicon oxide film 41 (SiO₂) is formed by oxidizing the semiconductor substrate 11, and a silicon nitride film 42 (SiN) is formed on the film by a chemical vapor deposition (CVD) technique. Then, resist patterns 43 and 44 are formed. The resist pattern 43 is formed on the n-type transistor formation region Tr1 formed in the subsequent manufacturing process, and the resist pattern 44 is formed on the p-type transistor formation region Tr2 formed in the subsequent manufacturing process. Note that the resist patterns 43 and 44 are formed in a manner that distances L₁ and L₂ from the interface between the insulating film 12 and the source/drain regions 22 and 32 formed in the subsequent manufacturing process to the end of the gate electrode 13 are different between the n-type transistor formation region Tr1 and the p-type transistor formation region Tr2.

That is, the resist patterns 43 and 44 are formed in a manner that a width L₄ of the resist pattern 43 is different from a width L₅ of the resist pattern 44 in the Y direction (gate length direction).

For example, an optical proximity effect correction (OPC) technique can be used to design the resist patterns 43 and 44 having different widths (the widths L₄ and L₅). The OPC technique is a technique in which the resist pattern is corrected in advance in a manner that the design pattern and the transfer pattern match.

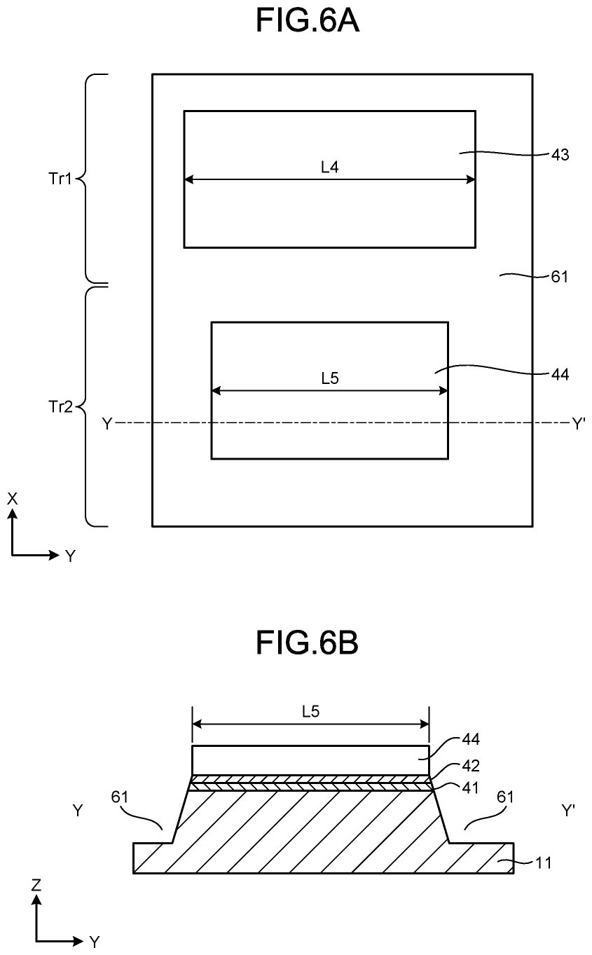

In a case where the insulating film 12 formed in the subsequent manufacturing process applies compressive stress in the Y direction (gate length direction) to the channel formation regions 21 and 31, the width L₄ of the resist pattern 43 is formed to be longer than the width L₅ of the resist pattern 44 as illustrated in FIG. 4A. In a case where the insulating film 12 applies tensile stress in the Y direction (gate length direction) to the channel formation regions 21 and 31, the width L₅ of the resist pattern 44 is formed to be longer than the width L₄ of the resist pattern 43 as illustrated in FIG. 5A. Note that, in the subsequent processes, to simplify explanation, a case where the insulating film 12 illustrated in FIGS. 4A and 4B applies compressive stress in the Y direction (gate length direction) to the channel formation regions 21 and 31 will be described with reference to FIGS. 6A to 10B. However, a similar process can be applied to a case where the insulating film 12 illustrated in FIGS. 5A and 5B applies tensile stress in the Y direction (gate length direction) to the channel formation regions 21 and 31.

As illustrated in FIGS. 6A and 6B, a groove 61 is formed in the semiconductor substrate 11 by a lithography technique, a dry etching technique, a wet etching technique, and the like using the resist patterns 43 and 44 as masks. After the groove 61 is formed, the resist patterns 43 and 44 are removed.

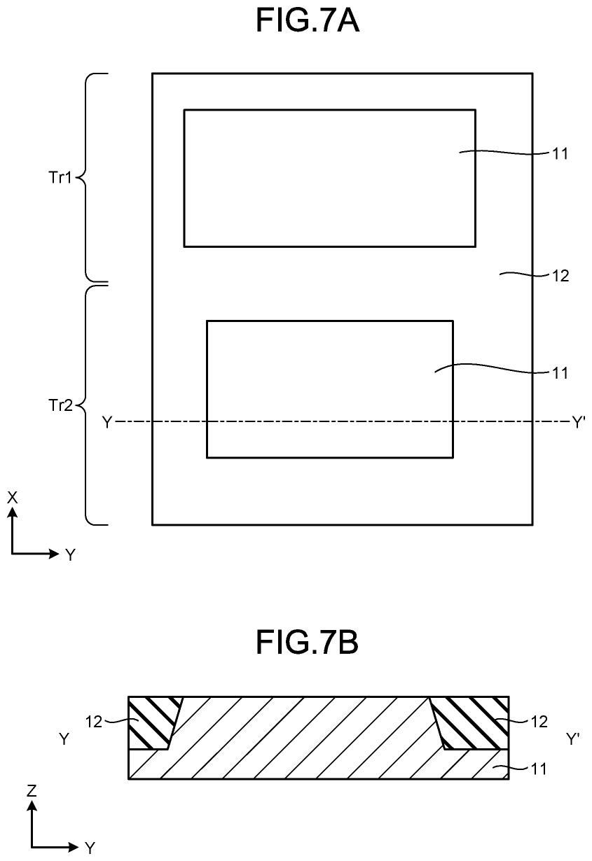

Next, as illustrated in FIGS. 7A and 7B, the insulating film 12 is embedded in the groove 61 by a CVD technique. The insulating film 12 is formed of, for example, a silicon oxide film (SiO₂) or a silicon nitride film (SiN). Then, the excessive insulating film 12 is removed by a chemical mechanical polishing (CMP) technique. As a result, the n-type transistor formation region Tr1 and the p-type transistor formation region Tr2 are formed, and the distances L₁ and L₂ from the interface between the insulating film 12 and the source/drain regions 22 and 32 manufactured in the subsequent process to the end of the gate electrode 13 are formed to be different between the n-type transistor formation region Tr1 and the p-type transistor formation region Tr2.

As described above, the magnitude relationship between the expansion coefficient of the insulating film 12 and the expansion coefficient of the semiconductor substrate 11 is different depending on the film formation process of the insulating film 12 and the high-temperature heat treatment process. In the present manufacturing method, a case is assumed in which a material in which the thermal expansion coefficient of the insulating film 12 is smaller than the thermal expansion coefficient of the semiconductor substrate 11 is used, and the force relationship is such that a force of expansion of the insulating film 12 is applied to the semiconductor substrate 11. That is, as described above, it is assumed that the insulating film 12 applies compressive stress in the Y direction (gate length direction) to the channel formation regions 21 and 31.

Therefore, in the present manufacturing method, the distances L₁ and L₂ from the interface between the insulating film 12 and the source/drain regions 22 and 32 manufactured in the subsequent process to the end of the gate electrode 13 are formed in a manner that the p-type transistor formation region Tr2 is shorter than the n-type transistor formation region Tr1 (L₁>L₂).

Subsequently, the channel formation regions 21 and 31 are formed. The channel formation region 21 is formed by introducing the p-type impurity into the p-type well region, and the channel formation region 31 is formed by introducing the n-type impurity into the n-type well region. Then, the silicon oxide film 41 (SiO₂) and the silicon nitride film 42 (SiN) are removed.

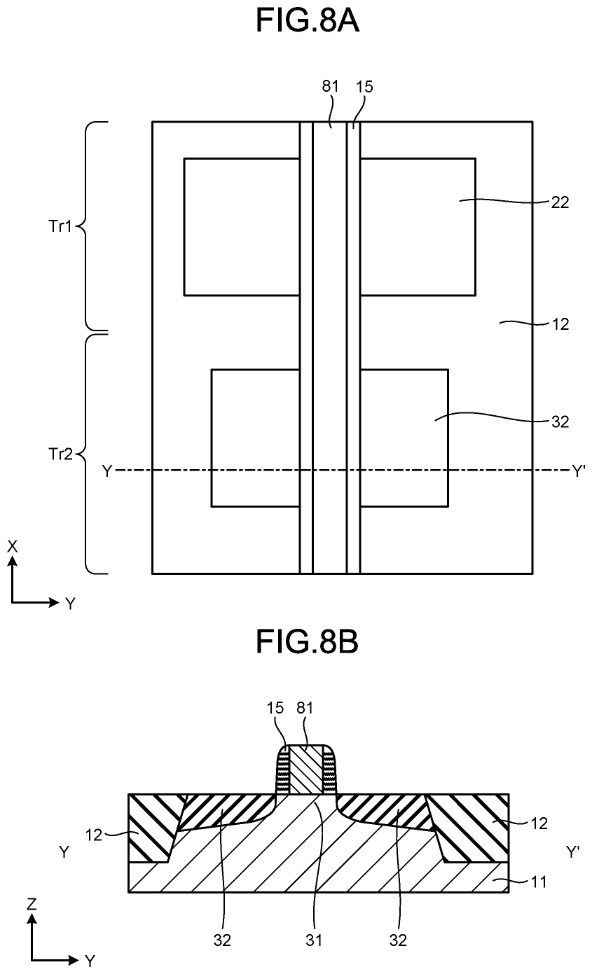

Next, as illustrated in FIGS. 8A and 8B, a dummy gate structure 81, the sidewall insulating film 15, and the source/drain regions 22 and 32 are formed on the semiconductor substrate 11. The dummy gate structure 81 includes a dummy gate, a dummy insulating film, and the like. The dummy gate is formed of, for example, polysilicon. The sidewall insulating film 15 is formed on the sidewall of the dummy gate structure 81, and is formed of the silicon oxide film (SiO₂), the silicon nitride film 42 (SiN), and the like.

Using the dummy gate structure 81 and the sidewall insulating film 15 as masks, a recess region (not illustrated) is formed in the semiconductor substrate 11 by a lithography technique, a dry etching technique, a wet etching technique, and the like. Subsequently, the source/drain regions 22 and 32 are formed in the recess region by epitaxial growth. Silicon carbide (SiC), silicon phosphide (SiP), and the like grown by epitaxial growth can be used for the source/drain regions 22 of the n-type transistor formation region Tr1. On the other hand, for the source/drain regions 32 of the p-type transistor formation region Tr2, silicon germanium (SiGe) and the like grown by epitaxial growth can be used. In FIG. 8A, the source/drain regions 22 and 32 are indicated by quadrangles, but the shape is not limited to a quadrangle. In addition, in FIG. 8B, the upper surfaces of the source/drain regions 22 and 32 are flush with the upper surface of the semiconductor substrate 11, but the present disclosure is not limited to this. For example, the upper surfaces of the source/drain regions 22 and 32 may be formed above the upper surface of the semiconductor substrate 11.

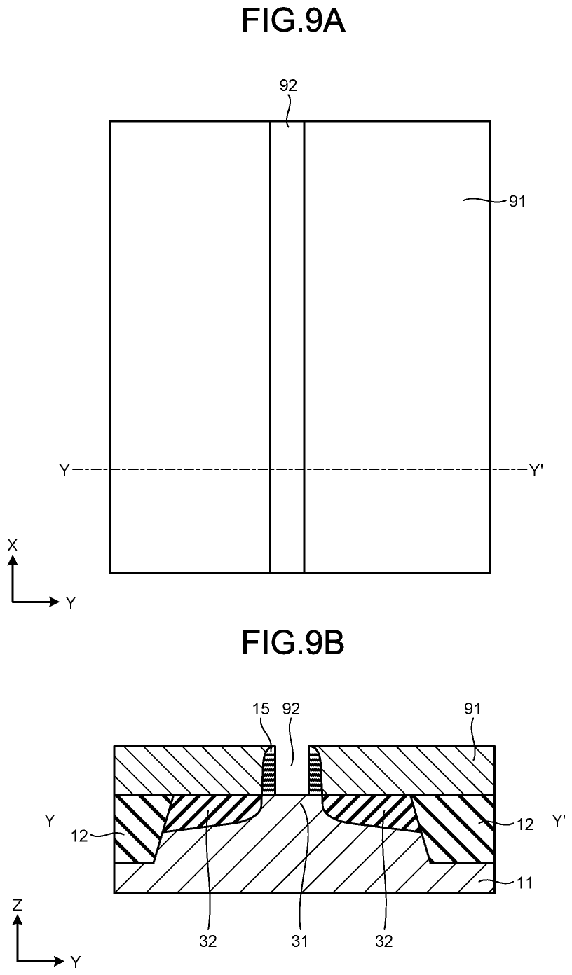

Next, as illustrated in FIGS. 9A and 9B, an insulating film 91 is formed on the semiconductor substrate 11. The insulating film 91 is formed of, for example, silicon oxide (SiO₂) by a CVD technique. After the insulating film 91 is formed, the insulating film 91 is removed by a CMP technique until the upper portion of the dummy gate structure 81 is exposed. Then, the dummy gate structure 81 is removed by dry etching, wet etching, and the like, and a groove 92 is formed between the pair of sidewall insulating films 15.

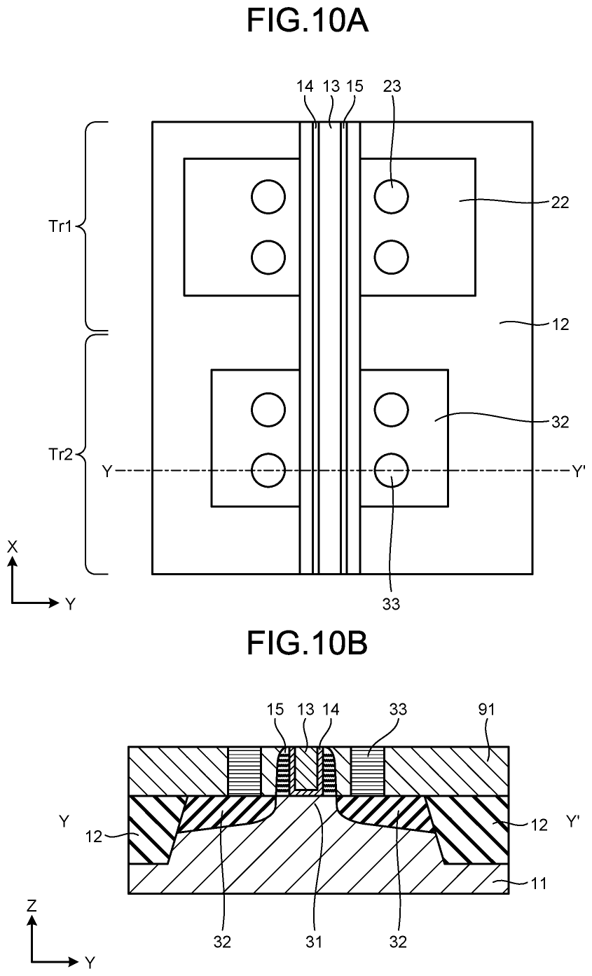

Next, as illustrated in FIGS. 10A and 10B, the gate insulating film 14, the gate electrode 13, and the contact electrodes 23 and 33 are formed on the semiconductor substrate 11. The gate insulating film 14 is formed on the bottom portion and the sidewalls of the groove 92, and is formed of a high dielectric constant (high-k) insulating film. Alternatively, the gate insulating film 14 may be formed at the bottom portion of the groove by oxidizing the surface of the semiconductor substrate 11. Subsequently, the gate electrode 13 is formed inside the groove 92 via the gate insulating film 14, and for example, a metal compound layer or a metal layer is used. Film formation of the gate electrode 13 is performed using, for example, an atomic layer deposition (ALD) technique or a physical vapor deposition (PVD) technique. Subsequently, an insulating film (not illustrated) is formed on the insulating film 91, and the contact electrodes 23 and 33 are formed. The contact electrodes 23 and 33 are formed of tungsten (W), copper (Cu), and the like, and are formed by a dry etching technique. As a result, the semiconductor device 1 including the n-type transistor formation region Tr1 and the p-type transistor formation region Tr2 is completed. For convenience of description, FIG. 10A illustrates a planar shape on the X-Y plane in which insulating film 91 is omitted.

In the present manufacturing method, a description has been made on the assumption that the compressive stress in the Y direction (gate length direction) is applied to the channel formation regions 21 and 31 by using the material having a thermal expansion coefficient smaller than the thermal expansion coefficient of the semiconductor substrate 11 for the material of the insulating film 12, but the present invention is not limited to this. For example, in a case where a material having a thermal expansion coefficient larger than the thermal expansion coefficient of the semiconductor substrate 11 is used for the material of the insulating film 12, the width L₅ of the resist pattern 44 is designed to be longer than the width L₄ of the resist pattern 43 in a case where a tensile stress in the Y direction (gate length direction) is applied to the channel formation regions 21 and 31.

Alternatively, a material having a thermal expansion coefficient smaller than the thermal expansion coefficient of the semiconductor substrate 11 may be used for the material of the insulating film 12 around the p-type transistor formation region Tr2, and a material having a thermal expansion coefficient larger than the thermal expansion coefficient of the semiconductor substrate 11 may be used for the material of the insulating film 12 around the n-type transistor formation region Tr1 for manufacturing.

1.6 Action and Effect

As described above, in the present embodiment, by providing a difference in the distance a from the interface between the insulating film 12 and the source/drain regions 22/32 to the end of the gate electrode 13 between the n-type transistor formation region Tr1 and the p-type transistor formation region Tr2, a difference is provided in compressive stress or tensile stress acting on the channel formation regions 21 and 31. As a result, it is possible to increase the carrier mobility of one transistor (p-type transistor or n-type transistor) of the p-type transistor and the n-type transistor formed on the same semiconductor substrate 11 and to suppress the reduction in the carrier mobility of the other transistor (n-type transistor or p-type transistor).

Note that a material having a thermal expansion coefficient smaller than the thermal expansion coefficient of the semiconductor substrate 11 may be used for the material of the insulating film 12 around the p-type transistor formation region Tr2, and a material having a thermal expansion coefficient larger than the thermal expansion coefficient of the semiconductor substrate 11 may be used for the material of the insulating film 12 around the n-type transistor formation region Tr1. In that case, in both the p-type transistor formation region Tr2 and the n-type transistor formation region Tr1, by making the distance a from the interface between the insulating film 12 and the source/drain regions 22/32 to the end of the gate electrode 13 close, the carrier mobility of both the p-type transistor and the n-type transistor can be increased.

Further, as described above, the source/drain regions 22 and 32 may be configured to apply a compressive stress or a tensile stress to the channel formation regions 21 and 31. Furthermore, such a configuration can be combined with a configuration in which a difference is provided in the distance a from the interface between the insulating film 12 and the source/drain regions 22/32 to the end of the gate electrode 13 between the p-type transistor and the n-type transistor. This makes it possible to more effectively increase the carrier mobility of both the p-type transistor and the n-type transistor.

### 2. Second Embodiment

2.1 Planar Shape of Semiconductor Device According to Second Embodiment

In the first embodiment, as illustrated in FIG. 3, the insulating film 12 is formed in a manner that distances L₁ and L₂ from the interface between the insulating film 12 and the source/drain regions 22 and 32 to the end of the gate electrode 13 in the Y direction (gate length direction) are different between the n-type transistor formation region Tr1 and the p-type transistor formation region Tr2 in any case. However, the insulating film 12 may be formed in a manner that the distance from the interface between the insulating film 12 and the source/drain regions 22 and 32 to the end of the gate electrode 13 is at least partially different between the n-type transistor formation region Tr1 and the p-type transistor formation region Tr2. In the second embodiment, this will be described.

In the description of the present embodiment, the same configuration, operation, and manufacturing method as those of the first embodiment are cited, and redundant description will be omitted.

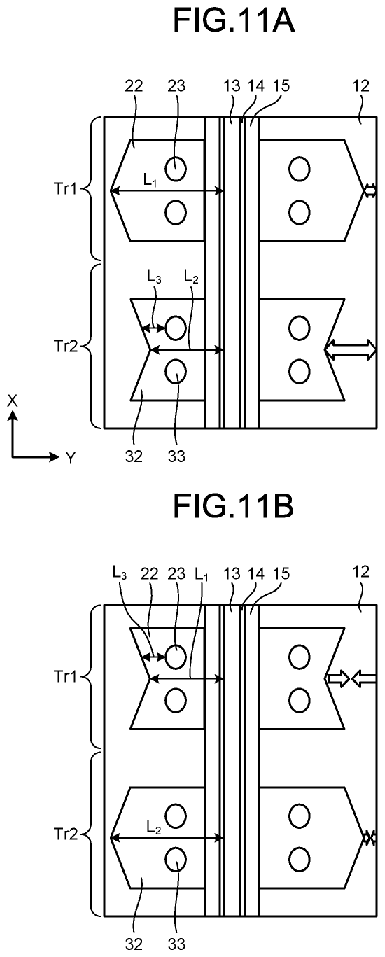

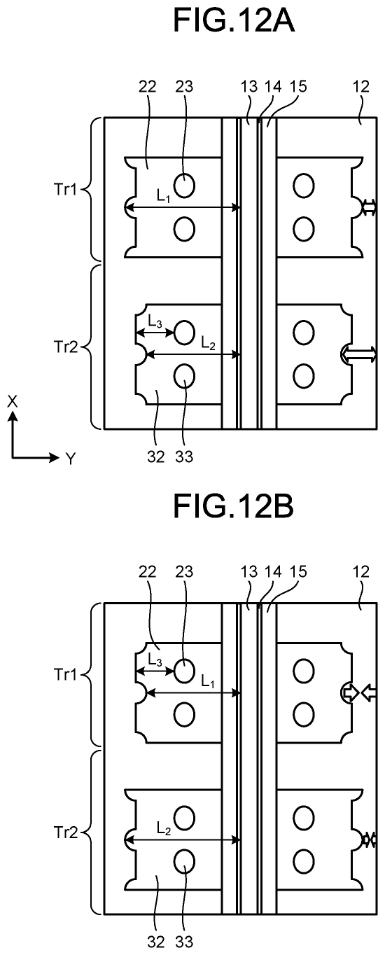

FIGS. 11A and 11B illustrate an example of the planar shape of the semiconductor device according to the first example of the second embodiment when FIG. 1 is viewed from the X-Y plane. FIGS. 12A and 12B illustrate an example of the planar shape of the semiconductor device according to the second example of the second embodiment when FIG. 1 is viewed from the X-Y plane.

Note that FIGS. 11A and 12A illustrate a planar shape in a case where a material having a thermal expansion coefficient smaller than the thermal expansion coefficient of the semiconductor substrate 11 is used for the material of the insulating film 12. That is, this is a case where the insulating film 12 applies compressive stress in the Y direction (gate length direction) to the channel formation regions 21 and 31. On the other hand, FIGS. 11B and 12B illustrate a planar shape in a case where a material having a thermal expansion coefficient larger than the thermal expansion coefficient of the semiconductor substrate 11 is used for the material of the insulating film 12. That is, this is a case where the insulating film 12 applies tensile stress in the Y direction (gate length direction) to the channel formation regions 21 and 31.

As illustrated in FIGS. 11A and 12A, in a case where a material having a thermal expansion coefficient smaller than the thermal expansion coefficient of the semiconductor substrate 11 is used for the material of the insulating film 12, in both the first example and the second example, a part of the insulating film 12 protrudes with respect to the source/drain regions 32 of the p-type transistor formation region Tr2. On the other hand, a part of the source/drain regions 22 of the n-type transistor formation region Tr1 protrudes with respect to the insulating film 12. Therefore, the insulating film 12 is formed in a manner that at least a part of the distances L₁ and L₂ from the interface between the insulating film 12 and the source/drain regions 22 and 32 to the end of the gate electrode 13 is different. In FIGS. 11A and 12A, in at least a part of the distances L₁ and L₂ from the interface between the insulating film 12 and the source/drain regions 22 and 32 to the end of the gate electrode 13, the p-type transistor formation region Tr2 is shorter than the n-type transistor formation region Tr1 (L₁>L₂).

This makes it possible to increase the compressive stress acting on the channel formation region 31 of the p-type transistor formation region Tr2 from the insulating film 12 and/or decrease the compressive stress acting on the channel formation region 21 of the n-type transistor formation region Tr1 from the insulating film 12 in the Y direction (gate length direction). As a result, the carrier mobility of the channel formation region 31 of the p-type transistor formation region Tr2 can be improved, and/or a decrease in the carrier mobility of the channel formation region 21 of the n-type transistor formation region Tr1 can be suppressed.

On the other hand, as illustrated in FIGS. 11B and 12B, in a case where a material having a thermal expansion coefficient larger than the thermal expansion coefficient of the semiconductor substrate 11 is used for the material of the insulating film 12, in both the first example and the second example, a part of the insulating film 12 protrudes with respect to the source/drain regions 22 of the n-type transistor formation region Tr1. On the other hand, a part of the source/drain regions 32 of the p-type transistor formation region Tr2 protrudes with respect to the insulating film 12. Therefore, the insulating film 12 is formed in a manner that at least a part of the distances L₁ and L₂ from the interface between the insulating film 12 and the source/drain regions 22 and 32 to the end of the gate electrode 13 is different. In FIGS. 11B and 12B, in at least a part of the distances L₁ and L₂ from the interface between the insulating film 12 and the source/drain regions 22 and 32 to the end of the gate electrode 13, the n-type transistor formation region Tr1 is shorter than the p-type transistor formation region Tr2 (L₁<L₂).

This makes it possible to increase the tensile stress acting on the channel formation region 31 of the n-type transistor formation region Tr1 from the insulating film 12 and/or decrease the tensile stress acting on the channel formation region 31 of the p-type transistor formation region Tr2 from the insulating film 12 in the Y direction (gate length direction). As a result, the carrier mobility of the channel formation region 21 of the n-type transistor formation region Tr1 can be improved, and/or a decrease in the carrier mobility of the channel formation region 31 of the p-type transistor formation region Tr2 can be suppressed.

In addition, in the present embodiment, in the n-type transistor formation region Tr1 and the p-type transistor formation region Tr2, the difference between the distances L₁ and L₂ from the interface between the insulating film 12 and the source/drain regions 22 and 32 to the end of the gate electrode 13 is desirably large. By adjusting the difference between the distances L₁ and L₂, it is possible to improve or suppress a decrease in the carrier mobility of the channel formation region 21 of the n-type transistor formation region Tr1 and to suppress a decrease in or improve the carrier mobility of the channel formation region 31 of the p-type transistor formation region Tr2 in a well-balanced manner.

In addition, the distance L₃ from the ends of the contact electrodes 23 and 33 to the interfaces between the insulating film 12 and the source/drain regions 22 and 32 is desirably equal to or larger than a margin required from the process accuracy. As a result, an increase in contact resistance and a connection failure can be suppressed, and the performance of the transistor can be improved.

However, as described above, the distance L₁ is desirably set to a large value within a range in which element isolation between adjacent transistors does not fail, and the distance L₂ is preferably as small as possible within a range in which it is ensured that the distance L₃ takes a value larger than zero.

Further, in the X direction (gate width direction), the insulating film 12 under the gate electrode 13 may protrude with respect to the channel formation regions 21 and 31, or the channel formation regions 21 and 31 may protrude with respect to the insulating film 12 under the gate electrode 13.

For example, in a case where a material having a thermal expansion coefficient smaller than the thermal expansion coefficient of the semiconductor substrate 11 is used for the material of the insulating film 12, the channel formation region 31 of the p-type transistor formation region Tr2 protrudes with respect to the insulating film 12 under the gate electrode 13 in the X direction (gate width direction). In addition, the insulating film 12 under the gate electrode 13 protrudes with respect to the channel formation region 21 of the n-type transistor formation region Tr1.

As a result, it is possible to decrease the compressive stress acting on the channel formation region 31 of the p-type transistor formation region Tr2 from the insulating film 12 and/or increase the compressive stress acting on the channel formation region 21 of the n-type transistor formation region Tr1 from the insulating film 12 in the X direction (gate width direction). As a result, decrease in the carrier mobility of the channel formation region 31 of the p-type transistor formation region Tr2 can be suppressed, and/or the carrier mobility of the channel formation region 21 of the n-type transistor formation region Tr1 can be improved.

On the other hand, in a case where a material having a thermal expansion coefficient larger than the thermal expansion coefficient of the semiconductor substrate 11 is used for the material of the insulating film 12, the channel formation region 21 of the n-type transistor formation region Tr1 protrudes with respect to the insulating film 12 under the gate electrode 13 in the X direction (gate width direction). In addition, the insulating film 12 under the gate electrode 13 protrudes with respect to the channel formation region 31 of the p-type transistor formation region Tr2.

This makes it possible to decrease the tensile stress acting on the channel formation region 31 of the n-type transistor formation region Tr1 from the insulating film 12 and/or increase the tensile stress acting on the channel formation region 31 of the p-type transistor formation region Tr2 from the insulating film 12 in the X direction (gate width direction). As a result, decrease in the carrier mobility of the channel formation region 21 of the n-type transistor formation region Tr1 can be suppressed, and/or the carrier mobility of the channel formation region 31 of the p-type transistor formation region Tr2 can be improved.

Note that the shape of the interface between the insulating film 12 and the source/drain regions 22 and 32 illustrated in FIGS. 11A and 11B and FIGS. 12A and 12B is merely an example, and is not limited to this. In addition, in order to create the shape of these interfaces, the resist pattern may be corrected to have a desired interface shape by the OPC technology described in the manufacturing process of the first embodiment.

2.2 Action and Effect

As described above, in the present embodiment, by providing a difference in at least a part of the distance a from the interface between the insulating film 12 and the source/drain regions 22/32 to the end of the gate electrode 13 between the n-type transistor formation region Tr1 and the p-type transistor formation region Tr2, a difference is provided in compressive stress or tensile stress acting on the channel formation regions 21 and 31. As a result, it is possible to increase the carrier mobility of one transistor (p-type transistor or n-type transistor) of the p-type transistor and the n-type transistor formed on the same semiconductor substrate 11 and to suppress the reduction in the carrier mobility of the other transistor (n-type transistor or p-type transistor).

Note that a material having a thermal expansion coefficient smaller than the thermal expansion coefficient of the semiconductor substrate 11 may be used for the material of the insulating film 12 around the p-type transistor formation region Tr2, and a material having a thermal expansion coefficient larger than the thermal expansion coefficient of the semiconductor substrate 11 may be used for the material of the insulating film 12 around the n-type transistor formation region Tr1. In that case, in both the p-type transistor formation region Tr2 and the n-type transistor formation region Tr1, by making at least a part of the distance a from the interface between the insulating film 12 and the source/drain regions 22/32 to the end of the gate electrode 13 close, the carrier mobility of both the p-type transistor and the n-type transistor can be increased.

Further, also in the present embodiment, the source/drain regions 22 and 32 may be configured to apply a compressive stress or a tensile stress to the channel formation regions 21 and 31. Furthermore, such a configuration can be combined with a configuration in which a difference is provided in the distance a from the interface between the insulating film 12 and the source/drain regions 22/32 to the end of the gate electrode 13 between the p-type transistor and the n-type transistor. This makes it possible to more effectively increase the carrier mobility of both the p-type transistor and the n-type transistor.

Further, in the X direction (gate width direction), the insulating film 12 under the gate electrode 13 may protrude with respect to the channel formation region 21/31, or the channel formation region 21/31 may protrude with respect to the insulating film 12 under the gate electrode 13. Furthermore, such a configuration can be combined with a configuration in which a difference is provided in at least a part of the distance a from the interface between the insulating film 12 and the source/drain regions 22/32 to the end of the gate electrode 13 between the p-type transistor and the n-type transistor, and/or a configuration in which the source/drain regions 22 and 32 apply compressive stress or tensile stress to the channel formation regions 21 and 31. This makes it possible to more effectively increase the carrier mobility of both the p-type transistor and the n-type transistor.

Furthermore, if the insulating film 12 is formed in a manner that the distance from the interface between the insulating film 12 and the source/drain regions 22 and 32 to the end of the gate electrode 13 is at least partially different between the n-type transistor formation region Tr1 and the p-type transistor formation region Tr2, the shape of the interface is arbitrary. Therefore, the flexibility of the design of the resist pattern can be enhanced.

Other configurations, operations, manufacturing methods, and effects may be similar to those of the first embodiment described above, and thus detailed description will be omitted here.

### 3. Third Embodiment

3.1 Configuration Example of Semiconductor Device According to First Example of Third Embodiment

In the first embodiment and the second embodiment, the case where the technology according to the present disclosure is applied to a so-called planar type semiconductor device having a two-dimensional structure has been described, but the present disclosure is not limited to this, and the technology according to the present disclosure is also applicable to a semiconductor device having a three-dimensional structure. In a third embodiment, a case where the technology according to the present disclosure is applied to a semiconductor device having a three-dimensional structure will be described.

In the description of the present embodiment, the same configuration, operation, and manufacturing method as those of the first or the second embodiment are cited, and redundant description will be omitted.

A semiconductor device having a three-dimensional structure includes, for example, a FinFET structure. The FinFET structure includes a fin portion formed by protruding a semiconductor substrate in a fin shape, and a channel formation region is formed in the fin portion under the gate electrode. Therefore, since the area of the channel formation region can be made larger than that of the semiconductor device having a two-dimensional structure, the drive current can be increased, and thus a higher-speed device can be realized.

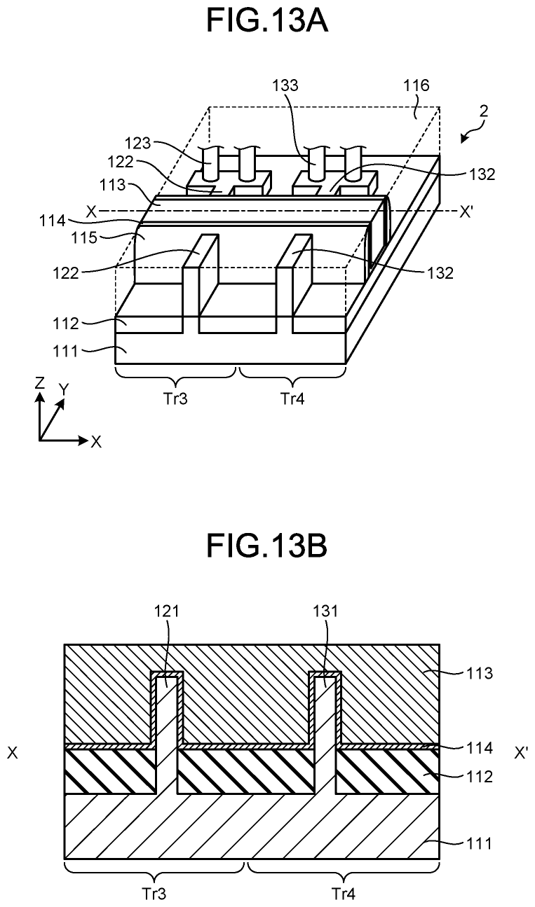

FIG. 13A is a view illustrating a configuration example of a semiconductor device according to a first example of the third embodiment, and illustrates a FinFET structure. FIG. 13B is a cross-sectional view illustrating a cross-sectional shape taken along an X-X′ plane illustrated in FIG. 13A. A semiconductor device 2 includes a semiconductor substrate 111, an element isolation film 112, an insulating film 116 (broken line region), an n-type transistor formation region Tr3, and a p-type transistor formation region Tr4.

For the semiconductor substrate 111, for example, a silicon substrate is used. In addition, the semiconductor substrate 111 includes a fin portion formed to protrude in a fin shape. The element isolation film 112 and the insulating film 116 (broken line region) are formed of, for example, an oxide film, and electrically insulate and isolate the n-type transistor formation region Tr3 and the p-type transistor formation region Tr4.

3.2 Configuration Example of Transistor According to First Example of Third Embodiment

The n-type transistor formation region Tr3 includes an n-type transistor including a gate electrode 113, a gate insulating film 114, a sidewall insulating film 115, and a pair of source/drain regions 122. A region under the gate electrode 113 in the semiconductor substrate 11 and sandwiched between the pair of source/drain regions 122 functions as a channel formation region 121 in which a channel is formed during driving. The n-type transistor is electrically connected to wiring or a circuit element (not illustrated) via a contact electrode 123 in contact with the source/drain regions 122.

Similarly, the p-type transistor formation region Tr4 includes a p-type transistor including the gate electrode 113, the gate insulating film 114, the sidewall insulating film 115, and a pair of source/drain regions 132. A region under the gate electrode 113 in the semiconductor substrate 111 and sandwiched between the pair of source/drain regions 132 functions as a channel formation region 131 in which a channel is formed during driving. The p-type transistor is electrically connected to wiring or a circuit element (not illustrated) via a contact electrode 133 in contact with the source/drain regions 132.

Although FIG. 13A illustrates a case where the gate structure including the gate electrode 113, the gate insulating film 114, and the sidewall insulating film 115 is shared by the n-type transistor and the p-type transistor, the present disclosure is not limited to such a structure, and different gate structures may be provided in the n-type transistor and the p-type transistor.

A p-type well region (not illustrated) into which a p-type impurity is introduced is formed in the semiconductor substrate 111 of the n-type transistor formation region Tr3, and an n-type well region (not illustrated) into which an n-type impurity is introduced is formed in the semiconductor substrate 11 of the p-type transistor formation region Tr4.

The channel formation region 121 is formed by introducing a p-type impurity into the p-type well region, and the channel formation region 131 is formed by introducing an n-type impurity into the n-type well region. In addition, since the channel formation regions 121 and 131 are formed in the fin portions in which the semiconductor substrate 111 is formed to protrude and the area of the channel formation region can be made larger than that of the semiconductor device having a two-dimensional structure, the drive current can be increased, and thus a higher-speed device can be realized.

The gate electrode 113 is formed in the n-type transistor formation region Tr3 and the p-type transistor formation region Tr4 in the X direction (gate width direction). Note that the X direction (gate width direction) corresponds to, for example, a first direction described in the claims. For the gate electrode 113, for example, a metal compound layer or a metal layer is used. As the metal layer, tungsten (W), titanium (Ti), titanium nitride (TiN), hafnium (Hf), hafnium silicide (HfSi), ruthenium (Ru), iridium (Ir), cobalt (Co), and the like can be selected. The metal layer may be a single-layer film, or may have a stacked structure in which a plurality of metal films is stacked to adjust the threshold voltage.

The gate insulating film 114 is formed of, for example, a high dielectric constant (high-k) insulating film having a thickness of 2 nm (nanometer) to 3 nm. As the high-k material, hafnium oxide (HfO₂), hafnium oxide silicide (HfSiO), tantalum oxide (Ta₂O₅), aluminum hafnium oxide (HfAlOₓ), and the like can be used. Alternatively, the gate insulating film 114 may be formed by oxidizing the surface of the semiconductor substrate 111.

The sidewall insulating film 115 is formed on the sidewall of the gate insulating film 114, and is formed of a silicon oxide film (SiO₂), a silicon nitride film (SiN), and the like.

The pair of source/drain regions 122 is formed in a pair of regions that are upper layer portions of the fin portions in which the semiconductor substrate 111 is formed to protrude and sandwich a region under the gate electrode 113 from the Y direction (gate length direction). Similarly, the pair of source/drain regions 132 is formed in a pair of regions that are upper layer portions of the fin portions in which the semiconductor substrate 111 is formed to protrude and sandwich the region under the gate electrode 113 from the Y direction (gate length direction). Note that the Y direction (gate length direction) corresponds to, for example, a second direction described in the claims.

In addition, a low resistance layer may be formed on the surfaces of the source/drain regions 122 and 132. The low resistance layer is a layer for reducing the resistance between the source/drain regions 122 and 132 and the contact electrodes 123 and 133, and is formed of, for example, cobalt (Co), nickel (Ni), platinum (Pt), a compound of them, and the like. Examples of the compound include metal silicide of these metals.

3.3 Planar Shape of Semiconductor Device According to First Example of Third Embodiment

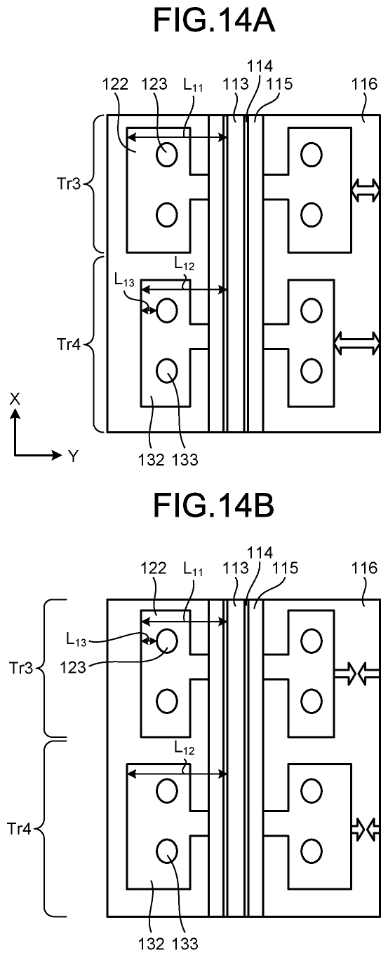

FIGS. 14A and 14B illustrate a planar shape of FIG. 13A on the X-Y plane. The insulating film 116 is formed in a manner that distances L₁₁ and L₁₂ from the interface between the insulating film 116 and the source/drain regions 122 and 132 to the end of the gate electrode 113 in the Y direction (gate length direction) are different between the n-type transistor formation region Tr3 and the p-type transistor formation region Tr4.

Therefore, in the present embodiment, as in the first embodiment, by providing a difference in the distance a from the interface between the insulating film 116 and the source/drain regions 122/132 to the end of the gate electrode 113 between the n-type transistor formation region Tr3 and the p-type transistor formation region Tr4, a difference is provided in compressive stress or tensile stress acting on the channel formation regions 121 and 131.

In the present embodiment, as a method for applying a compressive stress or a tensile stress to the channel formation regions 121 and 131, for example, a method for using the entire or at least a part of the element isolation film 112 as a stress liner film is conceivable. By forming the entire or at least a part of the element isolation film 112 as a stress liner film that generates strain in a predetermined direction, it is possible to apply compressive/tensile stress in a desired direction with respect to the channel formation regions 121 and 131.

Note that, in a case where the gate electrode 113 is not silicided, in a case where the element isolation film 112 is formed before silicidation of the gate electrode 113, or in a case where a silicide having high heat resistance is used for the gate electrode 113, a compressive stress can be applied to the transistor formation region also by using a material having a thermal expansion coefficient smaller than the thermal expansion coefficient of the semiconductor substrate 111 for the material of the insulating film 116 formed on the element isolation film 112. Similarly, in such a case, a tensile stress can be applied to the transistor formation region also by using a material having a thermal expansion coefficient larger than the thermal expansion coefficient of the semiconductor substrate 111 for the material of the insulating film 116 formed on the element isolation film 112.

FIG. 14A illustrates a case where the insulating film 116 applies compressive stress to the channel formation regions 121 and 131. As in the first embodiment, in the distances L₁₁ and L₁₂ from the interface between the insulating film 116 and the source/drain regions 122 and 132 to the end of the gate electrode 113, the p-type transistor formation region Tr4 is shorter than the n-type transistor formation region Tr3 (L₁₁>L₁₂). This makes it possible to increase the compressive stress acting on the channel formation region 131 of the p-type transistor formation region Tr4 from the insulating film 116 and/or decrease the compressive stress acting on the channel formation region 21 of the n-type transistor formation region Tr3 from the element isolation film 112 in the Y direction (gate length direction). As a result, the carrier mobility of the channel formation region 131 of the p-type transistor formation region Tr4 can be improved, and/or decrease in the carrier mobility of the channel formation region 121 of the n-type transistor formation region Tr3 can be suppressed.

FIG. 14B illustrates a case where the insulating film 116 applies tensile stress to the channel formation regions 121 and 131. As in the first embodiment, in the distances L₁₁ and L₁₂ from the interface between the insulating film 116 and the source/drain regions 122 and 132 to the end of the gate electrode 113, the n-type transistor formation region Tr3 is shorter than the p-type transistor formation region Tr4 (L₁₁<L₁₂). This makes it possible to increase the tensile stress acting on the channel formation region 131 of the n-type transistor formation region Tr3 from the insulating film 116 and/or decrease the tensile stress acting on the channel formation region 131 of the p-type transistor formation region Tr4 from the insulating film 116 in the Y direction (gate length direction). As a result, the carrier mobility of the channel formation region 121 of the n-type transistor formation region Tr3 can be improved, and/or decrease in the carrier mobility of the channel formation region 131 of the p-type transistor formation region Tr4 can be suppressed.

In the n-type transistor formation region Tr3 and the p-type transistor formation region Tr4, the difference between the distances L₁₁ and L₁₂ from the interface between the insulating film 116 and the source/drain regions 122 and 132 to the end of the gate electrode 113 is desirably large. By adjusting the difference between the distances L₁₁ and L₁₂, it is possible to improve or suppress a decrease in the carrier mobility of the channel formation region 121 of the n-type transistor formation region Tr3 and to suppress or improve a decrease in the carrier mobility of the channel formation region 131 of the p-type transistor formation region Tr4 in a well-balanced manner.

In addition, since the source/drain regions 122 of the n-type transistor formation region Tr3 formed of silicon carbide (SiC), silicon phosphide (SiP), and the like grown by epitaxial growth apply tensile stress in the Y direction (gate length direction) to the channel formation region 121, carrier mobility of the channel formation region 121 can be more effectively improved.

Similarly, since the source/drain regions 132 of the p-type transistor formation region Tr4 formed of silicon germanium (SiGe) and the like grown by epitaxial growth apply compressive stress in the Y direction (gate length direction) to the channel formation region 131, carrier mobility of the channel formation region 131 can be more effectively improved.

A distance L₁₃ from the ends of the contact electrodes 123 and 133 to the interfaces between the insulating film 116 and the source/drain regions 122 and 132 is desirably equal to or larger than a margin required from the process accuracy. As a result, an increase in contact resistance and a connection failure can be suppressed, and the performance of the transistor can be improved.

However, similarly to the distance L₁ described above, the distance L₁₁ is desirably set to a large value within a range in which element isolation between adjacent transistors does not fail.

On the other hand, if the value of a distance L₁₂ is too short, when contact electrodes 123 and 133 are formed with respect to the source/drain regions 122 and 132, defects may occur such as those in which a part of the contact electrodes 123 and 133 may deviate from the upper surfaces of the source/drain regions 122 and 132 and may be formed up to the side surfaces of the source/drain regions 122 and 132, or the contact electrodes 123 and 133 may reach the element isolation film 112 under the source/drain regions 122 and 132. Therefore, similarly to the distance L₂, the distance L₁₂ is desirably set in a manner that the distance L₁₃ takes a value larger than 0. However, the distance L₁₂ is preferably as small as possible as long as the distance L₁₂ is within a range that does not cause a connection failure.

In the present embodiment, in both the source/drain regions 122 and 132, the distance from the interface between the insulating film 116 and the source/drain regions 122 and 132 to the end of the gate electrode 113 is formed to be different between the n-type transistor formation region Tr3 and the p-type transistor formation region Tr4, but the present disclosure is not limited to this. In any one of the source/drain regions 122 and 132, the distance from the interface between the insulating film 116 and the source/drain regions 122 and 132 to the end of the gate electrode 113 may be formed to be different between the n-type transistor formation region Tr3 and the p-type transistor formation region Tr4. That is, the distance from the interface between one of the source region and the drain region of the source/drain regions 122 and 132 and the insulating film 116 to the end of the gate electrode 113 may be different between the n-type transistor formation region Tr3 and the p-type transistor formation region Tr4.

Further, as in the second embodiment, the insulating film 116 under the gate electrode 113 may protrude with respect to the channel formation region 121/131, or the channel formation region 121/131 may protrude with respect to the insulating film 116 under the gate electrode 113 in the X direction (gate width direction).

3.4 Configuration Example of Semiconductor Device According to Second Example of Third Embodiment

Examples of the semiconductor device having a three-dimensional structure include a nanowire (nanowire) structure. The nanowire structure is formed in a manner that a channel formation region formed of an extremely thin nanowire is surrounded by a gate insulating film. This makes it possible to achieve both sharp on/off switching characteristics and miniaturization.

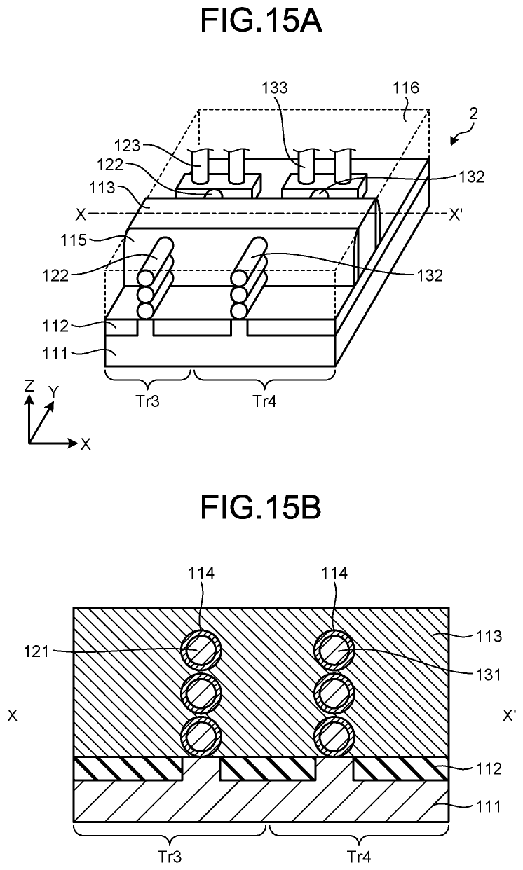

FIG. 15A is a view illustrating a configuration example of a semiconductor device according to a second example of the third embodiment, and illustrates a nanowire structure. FIG. 15B is a cross-sectional view illustrating a cross-sectional shape taken along the X-X′ plane illustrated in FIG. 15A. A plurality of extremely thin nanowires is stacked in each of the n-type transistor formation region Tr3 and the p-type transistor formation region Tr4. In FIGS. 15A and 15B, the number of nanowires to be stacked is 3, but the number is not limited to this.

As illustrated in FIGS. 15A and 15B, each nanowire of the n-type transistor formation region Tr3 has a structure in which the periphery of the channel formation region 121 formed under the gate electrode 113 is covered with the gate insulating film 114. In addition, a pair of source/drain regions 122 is formed to sandwich the channel formation region 121. The region sandwiched between the pair of source/drain regions 122 functions as a channel formation region 121 in which a channel is formed during driving. The n-type transistor is electrically connected to wiring or a circuit element (not illustrated) via a contact electrode 123 in contact with the source/drain regions 122.

Similarly, as illustrated in FIGS. 15A and 15B, each nanowire of the p-type transistor formation region Tr4 has a structure in which the periphery of the channel formation region 131 formed under the gate electrode 113 is covered with the gate insulating film 114. In addition, a pair of source/drain regions 132 is formed to sandwich the channel formation region 121. The region sandwiched between the pair of source/drain regions 132 functions as a channel formation region 131 in which a channel is formed during driving. The p-type transistor is electrically connected to wiring or a circuit element (not illustrated) via a contact electrode 133 in contact with the source/drain regions 132.

Although FIG. 15A illustrates a case where the gate structure including the gate electrode 113 and the sidewall insulating film 115 is shared by the n-type transistor and the p-type transistor, the present disclosure is not limited to such a structure, and different gate structures may be provided in the n-type transistor and the p-type transistor.

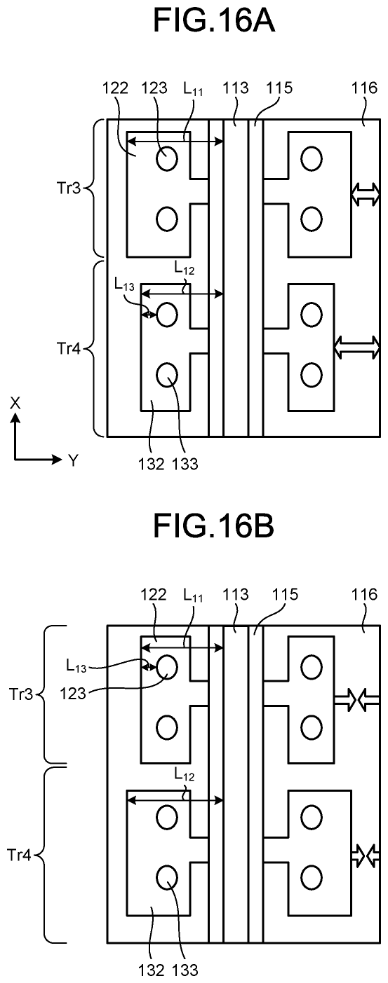

The planar shape of the present embodiment illustrated in FIG. 15A on the X-Y plane is illustrated in FIGS. 16A and 16B. In the present embodiment, similarly to the semiconductor device according to the first example of the third embodiment, by providing a difference in the distance a from the interface between the insulating film 116 and the source/drain regions 122/132 to the end of the gate electrode 113 between the n-type transistor formation region Tr3 and the p-type transistor formation region Tr4, a difference is provided in compressive stress or tensile stress acting on the channel formation regions 121 and 131.

In the description of the present embodiment, the same configuration and operation as those of the semiconductor device of the first example of the third embodiment are cited, and redundant description will be omitted.

3.5 Configuration Example of Semiconductor Device According to Third Example of Third Embodiment

Examples of the semiconductor device having a three-dimensional structure include a nanosheet structure. Unlike the nanowire in which the channel formation region is formed in a nanowire shape, in the nanosheet structure, the channel formation region is formed in a nanosheet shape to be surrounded by the gate insulating film. As a result, the contact area of the channel formation region can be increased, and the current can be increased.

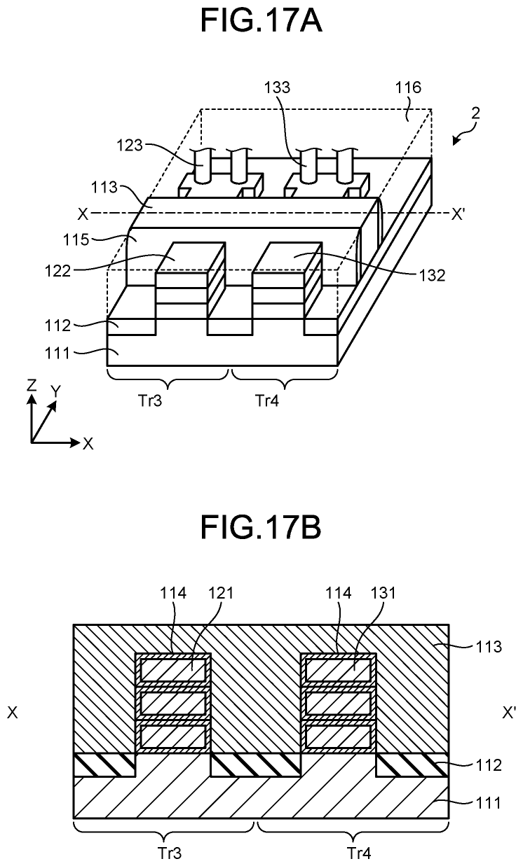

FIG. 17A is a view illustrating a configuration example of a semiconductor device according to a third example of the third embodiment, and illustrates a nanosheet structure. FIG. 17B is a cross-sectional view illustrating a cross-sectional shape taken along the X-X′ plane illustrated in FIG. 17A. A plurality of nanosheets is stacked in each of the n-type transistor formation region Tr3 and the p-type transistor formation region Tr4. In FIGS. 17A and 17B, the number of nanosheets to be stacked is 3, but the number is not limited to this.

Each nanosheet of the n-type transistor formation region Tr3 has a structure in which the periphery of the nanosheet-shaped channel formation region 121 formed under the gate electrode 113 is covered with the gate insulating film 114. In addition, a pair of source/drain regions 122 is formed to sandwich the channel formation region 121. The region sandwiched between the pair of source/drain regions 122 functions as a channel formation region 121 in which a channel is formed during driving. The n-type transistor is electrically connected to wiring or a circuit element (not illustrated) via a contact electrode 23 in contact with the source/drain regions 22.

Similarly, each nanosheet of the p-type transistor formation region Tr4 has a structure in which the periphery of the nanosheet-shaped channel formation region 131 formed under the gate electrode 113 is covered with the gate insulating film 114. In addition, a pair of source/drain regions 132 is formed to sandwich the channel formation region 121. The region sandwiched between the pair of source/drain regions 132 functions as a channel formation region 131 in which a channel is formed during driving. The p-type transistor is electrically connected to wiring or a circuit element (not illustrated) via the contact electrode 123 in contact with the source/drain regions 122.

Although FIG. 17A illustrates a case where the gate structure including the gate electrode 113 and the sidewall insulating film 115 is shared by the n-type transistor and the p-type transistor, the present disclosure is not limited to such a structure, and different gate structures may be provided in the n-type transistor and the p-type transistor.

The planar shape of the present embodiment illustrated in FIG. 17A on the X-Y plane is similar to the planar shape of the semiconductor device according to the second example of the third embodiment on the X-Y plane, and is illustrated in FIGS. 16A and 16B. In the present embodiment, similarly to the semiconductor devices according to the first example and the second example of the third embodiment, by providing a difference in the distance a from the interface between the insulating film 116 and the source/drain regions 122/132 to the end of the gate electrode 113 between the n-type transistor formation region Tr3 and the p-type transistor formation region Tr4, a difference is provided in compressive stress or tensile stress acting on the channel formation regions 121 and 131.

In the description of the present embodiment, the same configurations and operations as those of the semiconductor devices according to the first example and the second example of the third embodiment are cited, and redundant description will be omitted.

3.6 Action and Effect

As described above, in the present embodiment, by providing a difference in at least a part of the distance a from the interface between the insulating film 116 and the source/drain regions 122/132 to the end of the gate electrode 113 between the n-type transistor formation region Tr3 and the p-type transistor formation region Tr4, a difference is provided in compressive stress or tensile stress acting on the channel formation regions 121 and 131. As a result, it is possible to increase the carrier mobility of one transistor (p-type transistor or n-type transistor) of the p-type transistor and the n-type transistor formed on the same semiconductor substrate 111 and to suppress the reduction in the carrier mobility of the other transistor (n-type transistor or p-type transistor).

Note that the stress generation direction of the stress liner film disposed around the p-type transistor formation region Tr4 and the stress generation direction of the stress liner film disposed around the n-type transistor formation region Tr3 may be opposite. In that case, the carrier mobility of both the p-type transistor and the n-type transistor can be increased.

Further, the source/drain regions 122 and 132 may be configured to apply a compressive stress or a tensile stress to the channel formation regions 121 and 131. Furthermore, such a configuration can be combined with a configuration in which a difference is provided in the distance a from the interface between the insulating film 116 and the source/drain regions 122/132 to the end of the gate electrode 113 between the p-type transistor and the n-type transistor. This makes it possible to more effectively increase the carrier mobility of both the p-type transistor and the n-type transistor.

Further, in the X direction (gate width direction), the insulating film 116 under the gate electrode 113 may protrude with respect to the channel formation region 121/131, or the channel formation region 121/131 may protrude with respect to the insulating film 116 under the gate electrode 113. Furthermore, such a configuration can be combined with a configuration in which a difference is provided in the distance a from the interface between the insulating film 116 and the source/drain regions 122/132 to the end of the gate electrode 113 between the p-type transistor and the n-type transistor, and/or a configuration in which the source/drain regions 122 and 132 apply compressive stress or tensile stress to the channel formation regions 121 and 131. This makes it possible to more effectively increase the carrier mobility of both the p-type transistor and the n-type transistor.

Note that the effects described in the present embodiment are merely examples and are not limited, and other effects may be provided. In addition, in the present embodiment, a single gate structure including a single gate electrode applied to an inverter and the like has been described, but the present disclosure is not limited to this, and a multi-gate structure including a plurality of gate electrodes can also be applied. Furthermore, in the present embodiment, a structure including a single fin portion, a structure in which a single stacked nanowire is formed, and a structure in which a single stacked nanosheet is formed have been described, but the present disclosure is not limited these, and a structure in which a plurality of fin portions is formed side by side, a structure in which a plurality of stacked nanowires is formed side by side, and a structure in which a plurality of stacked nanosheets is formed side by side can also be applied.

### 4. Fourth Embodiment

4.1 Cross-Sectional Shape of Semiconductor Device According to Fourth Embodiment

In the first embodiment to the third embodiment, by providing a difference in at least a part of the distance a from the interface between the insulating film and the source/drain regions to the end of the gate electrode between the n-type transistor formation region and the p-type transistor formation region in the planar shape on the X-Y plane in FIGS. 1, 13A, 15A, and 17A, a difference is provided in compressive stress or tensile stress acting on the channel formation regions.

However, providing a difference in at least a part of the distance a from the interface between the insulating film and the source/drain region to the end of the gate electrode between the n-type transistor formation region and the p-type transistor formation region is not limited to the planar shape on the X-Y plane, and may be a cross-sectional shape on an X-Z plane. In the present embodiment, this will be described.

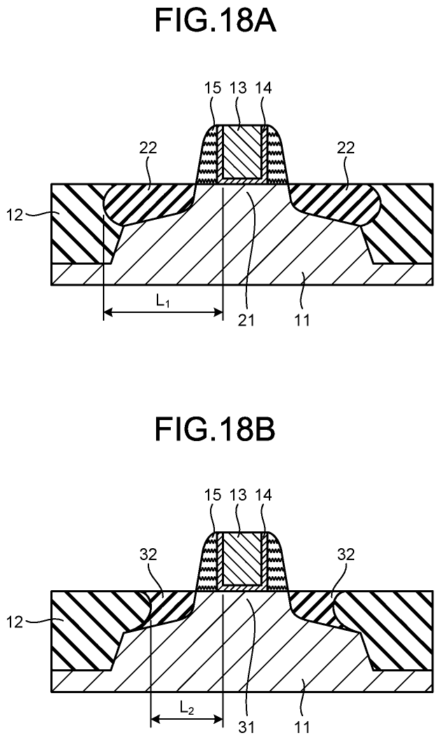

FIG. 18A is a cross-sectional view illustrating an example of a cross-sectional shape of a semiconductor device according to a fourth embodiment, and illustrates a cross-sectional view which is a cross-sectional shape taken along an A-A′ plane illustrated in FIG. 1. FIG. 18B is a cross-sectional view illustrating an example of another cross-sectional shape of a semiconductor device according to a fourth embodiment, and illustrates a cross-sectional view which is a cross-sectional shape taken along a B-B′ plane illustrated in FIG. 1. Note that FIGS. 18A and 18B illustrate a case where the insulating film 12 applies compressive stress in the Y direction (gate length direction) to the channel formation regions 21 and 31. In addition, in the description of the present embodiment, the same configuration, operation, and manufacturing method as those of the first embodiment are cited, and redundant description will be omitted.

As illustrated in FIG. 18A, a part of the source/drain regions 22 of the n-type transistor formation region Tr1 protrudes with respect to the insulating film 12. On the other hand, as illustrated in FIG. 18B, a part of the insulating film 12 protrudes with respect to the source/drain regions 32 of the p-type transistor formation region Tr2. Therefore, the insulating film 12 is formed in a manner that at least a part of the distances L₁ and L₂ from the interface between the insulating film 12 and the source/drain regions 22 and 32 to the end of the gate electrode 13 is different. In FIGS. 18A and 18B, in at least a part of the distances L₁ and L₂ from the interface between the insulating film 12 and the source/drain regions 22 and 32 to the end of the gate electrode 13, the p-type transistor formation region Tr2 is shorter than the n-type transistor formation region Tr1 (L₁>L₂).

This makes it possible to increase the compressive stress acting on the channel formation region 31 of the p-type transistor formation region Tr2 from the insulating film 12 and/or decrease the compressive stress acting on the channel formation region 21 of the n-type transistor formation region Tr1 from the insulating film 12 in the Y direction (gate length direction). As a result, the carrier mobility of the channel formation region 31 of the p-type transistor formation region Tr2 can be improved, and/or a decrease in the carrier mobility of the channel formation region 21 of the n-type transistor formation region Tr1 can be suppressed.

On the other hand, in a case where the insulating film 12 applies tensile stress in the Y direction (gate length direction) to the channel formation regions 21 and 31, a part of the insulating film 12 may protrude with respect to the source/drain regions 22 of the n-type transistor formation region Tr1, and a part of the source/drain regions 32 of the p-type transistor formation region Tr2 may protrude with respect to the insulating film 12.

This makes it possible to increase the tensile stress acting on the channel formation region 31 of the n-type transistor formation region Tr1 from the insulating film 12 and/or decrease the tensile stress acting on the channel formation region 31 of the p-type transistor formation region Tr2 from the insulating film 12 in the Y direction (gate length direction). As a result, the carrier mobility of the channel formation region 21 of the n-type transistor formation region Tr1 can be improved, and/or a decrease in the carrier mobility of the channel formation region 31 of the p-type transistor formation region Tr2 can be suppressed.

Note that the shape of the interface between the insulating film 12 and the source/drain regions 22 and 32 is merely an example, and is not limited to this.

In addition, in the present embodiment, the case where the technology according to the present disclosure is applied to a so-called planar type semiconductor device having a two-dimensional structure has been described, but this is merely an example, and the technology according to the present disclosure is also applicable to a semiconductor device having a three-dimensional structure described in the third embodiment. For example, in a case where the insulating film 116 applies compressive stress in the Y direction (gate length direction) to the channel formation regions 121 and 131, a part of the source/drain regions 122 of the n-type transistor formation region Tr3 may protrude with respect to the insulating film 116, and a part of the insulating film 116 may protrude with respect to the source/drain regions 132 of the p-type transistor formation region Tr4. On the other hand, in a case where the insulating film 116 applies tensile stress in the Y direction (gate length direction) to the channel formation regions 121 and 131, a part of the insulating film 116 may protrude with respect to the source/drain regions 122 of the of the n-type transistor formation region Tr3, and a part of the source/drain regions 132 of the p-type transistor formation region Tr4 may protrude with respect to the insulating film 116.

4.2 Action and Effect

As described above, in the present embodiment, by providing a difference in at least a part of the distance a from the interface between the insulating film and the source/drain regions to the end of the gate electrode between the n-type transistor formation region and the p-type transistor formation region in the cross-sectional shape on the X-Z plane, a difference is provided in compressive stress or tensile stress acting on the channel formation regions. As a result, it is possible to increase the carrier mobility of one transistor (p-type transistor or n-type transistor) of the p-type transistor and the n-type transistor formed on the same semiconductor substrate and to suppress the reduction in the carrier mobility of the other transistor (n-type transistor or p-type transistor).

Note that a material having a thermal expansion coefficient smaller than the thermal expansion coefficient of the semiconductor substrate may be used for the material of the insulating film around the p-type transistor formation region, and a material having a thermal expansion coefficient larger than the thermal expansion coefficient of the semiconductor substrate may be used for the material of the insulating film around the n-type transistor formation region. In that case, in both the p-type transistor formation region and the n-type transistor formation region, by making at least a part of the distance a from the interface between the insulating film and the source/drain regions to the end of the gate electrode close in the cross-sectional shape on the X-Z plane, the carrier mobility of both the p-type transistor and the n-type transistor can be increased.

Further, in the X direction (gate width direction), the insulating film under the gate electrode may protrude with respect to the channel formation region, or the channel formation region may protrude with respect to the insulating film under the gate electrode. Furthermore, such a configuration can be combined with a configuration in which a difference is provided in the distance a from the interface between the insulating film and the source/drain regions to the end of the gate electrode between the p-type transistor and the n-type transistor, and/or a configuration in which the source/drain regions apply compressive stress or tensile stress to the channel formation regions in the cross-sectional shape on the X-Z plane. This makes it possible to more effectively increase the carrier mobility of both the p-type transistor and the n-type transistor.

Note that the effects described in the present embodiment are merely examples and are not limited, and other effects may be provided.

### 5. Fifth Embodiment

5.1 Configuration Example of Semiconductor Device According to Fifth Embodiment

In the semiconductor devices according to the first embodiment to fourth embodiment, a stress film application film for applying compressive and tensile stresses in the Y direction (gate length direction) to the channel formation region may be further formed.

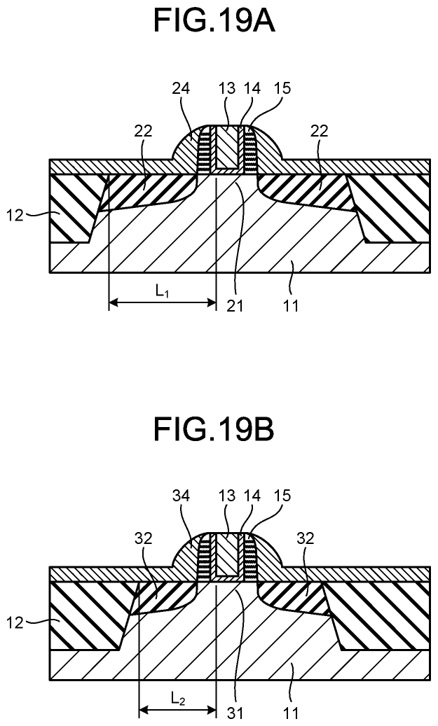

FIG. 19A is a cross-sectional view illustrating an example of a cross-sectional shape of a semiconductor device according to a fifth embodiment, and illustrates a cross-sectional view taken along the A-A′ plane illustrated in FIG. 1. FIG. 19B is a cross-sectional view illustrating an example of another cross-sectional shape of a semiconductor device according to a fifth embodiment, and illustrates a cross-sectional view taken along the B-B′ plane illustrated in FIG. 1. Note that FIGS. 19A and 19B illustrate a case where the insulating film 12 applies compressive stress in the Y direction (gate length direction) to the channel formation regions 21 and 31. In addition, in the description of the present embodiment, the same configuration, operation, and manufacturing method as those of the first embodiment are cited, and redundant description will be omitted.

In FIGS. 19A and 19B, in at least a part of the distances L₁ and L₂ from the interface between the insulating film 12 and the source/drain regions 22 and 32 to the end of the gate electrode 13, the p-type transistor formation region Tr2 is shorter than the n-type transistor formation region Tr1 (L₁>L₂). Therefore, the carrier mobility of the channel formation region 31 of the p-type transistor formation region Tr2 can be improved, and/or decrease in the carrier mobility of the channel formation region 21 of the n-type transistor formation region Tr1 can be suppressed.

As illustrated in FIG. 19A, in the present embodiment, a stress application film 24 is further formed on the source/drain regions 22 of the n-type transistor formation region Tr1 and on both sides of the gate electrode 13. The stress application film 24 is formed of, for example, a silicon nitride film (SiN), and applies tensile stress in the Y direction (gate length direction) to the channel formation region 21. Thus, the carrier mobility of the n-type transistor can be improved.

On the other hand, as illustrated in FIG. 19B, in the present embodiment, a stress application film 34 is further formed on the source/drain regions 32 of the p-type transistor formation region Tr2 and on both sides of the gate electrode 13. The stress application film 34 is formed of, for example, a silicon nitride film (SiN), and applies compressive stress in the Y direction (gate length direction) to the channel formation region 31. Thus, the carrier mobility of the p-type transistor can be improved.

In addition, in the present embodiment, the case where the technology according to the present disclosure is applied to a so-called planar type semiconductor device having a two-dimensional structure has been described, but this is merely an example, and the technology according to the present disclosure is also applicable to a semiconductor device having a three-dimensional structure described in the third embodiment. For example, in the n-type transistor formation region Tr3, a stress application film capable of applying a tensile stress in the Y direction (gate length direction) to the channel formation region 121 may be formed. On the other hand, in the p-type transistor formation region Tr4, a stress application film capable of applying a compressive stress in the Y direction (gate length direction) to the channel formation region 131 may be formed.

5.2 Action and Effect

As described above, in the present embodiment, in addition to providing a difference in at least a part of the distance a from the interface between the insulating film and the source/drain regions to the end of the gate electrode between the n-type transistor formation region and the p-type transistor formation region, a stress application film for applying compressive stress or tensile stress to the channel formation region of the n-type transistor formation region and the channel formation region of the p-type transistor formation region is formed. A stress application film capable of applying tensile stress in the Y direction (gate length direction) is formed in the n-type transistor formation region, and a stress application film capable of applying compressive stress in the Y direction (gate length direction) is formed in the p-type transistor formation region. This makes it possible to more effectively increase the carrier mobility of both the n-type transistor and the p-type transistor.

Note that a material having a thermal expansion coefficient smaller than the thermal expansion coefficient of the semiconductor substrate may be used for the material of the insulating film around the p-type transistor formation region, and a material having a thermal expansion coefficient larger than the thermal expansion coefficient of the semiconductor substrate may be used for the material of the insulating film around the n-type transistor formation region. In that case, in both the p-type transistor formation region and the n-type transistor formation region, by making at least a part of the distance a from the interface between the insulating film and the source/drain regions to the end of the gate electrode close, the carrier mobility of both the p-type transistor and the n-type transistor can be increased.

Further, in the X direction (gate width direction), the insulating film under the gate electrode may protrude with respect to the channel formation region, or the channel formation region may protrude with respect to the insulating film under the gate electrode. Furthermore, such a configuration can be combined with a configuration in which a difference is provided in the distance a from the interface between the insulating film and the source/drain regions to the end of the gate electrode between the p-type transistor and the n-type transistor, a configuration in which the stress application film applies compressive stress or tensile stress to the channel formation region of the n-type transistor formation region and the channel formation region of the p-type transistor formation region, or a configuration in which the source/drain regions apply compressive stress or tensile stress to the channel formation region. This makes it possible to more effectively increase the carrier mobility of both the p-type transistor and the n-type transistor.

Note that the effects described in the present embodiment are merely examples and are not limited, and other effects may be provided.

### 6. Others

In the present disclosure, for example, in order to improve carrier mobility, in a case where a material having a thermal expansion coefficient smaller than the thermal expansion coefficient of the semiconductor substrate is used for the material of the insulating film, a configuration has been described in which, the distance a in the p-type transistor formation region is decreased and the distance a in the n-type transistor formation region is increased. Similarly, in a case where a material having a thermal expansion coefficient larger than the thermal expansion coefficient of the semiconductor substrate is used for the material of the insulating film, a configuration has been described in which, the distance a in the n-type transistor formation region is decreased and the distance a in the p-type transistor formation region is increased. However, the present disclosure is not limited to this.

For example, in a case where a material having a thermal expansion coefficient smaller than the thermal expansion coefficient of the semiconductor substrate is used for the material of the insulating film, a configuration may be used in which, the distance a in the p-type transistor formation region is increased and the distance a in the n-type transistor formation region is decreased. Similarly, in a case where a material having a thermal expansion coefficient larger than the thermal expansion coefficient of the semiconductor substrate is used for the material of the insulating film, a configuration may be used in which, the distance a in the n-type transistor formation region is increased and the distance a in the p-type transistor formation region is decreased. As a result, for example, variations in characteristics of the transistor can be suppressed, and the performance of the transistor can be improved.

The operation and the manufacturing method are the same as those described in the first embodiment to fifth embodiment. Furthermore, the effects described in the present specification are merely examples and are not limited, and other effects may be provided.

In addition, in the above-described embodiment, silicon carbide (SiC), silicon phosphide (SiP), and the like grown by epitaxial growth may be used for the source/drain regions 22 of the n-type transistor formation region Tr1. This makes it possible to apply a tensile stress to the channel formation region 21 by the epitaxial growth film in addition to a tensile stress generated by a difference in thermal expansion coefficient between the insulating film 12 and the semiconductor substrate 11, and thus the carrier mobility of the channel formation region 21 can be more effectively improved.

Similarly, for the source/drain regions 32 of the p-type transistor formation region Tr2, silicon germanium (SiGe) and the like grown by epitaxial growth may be used. This makes it possible to apply a compressive stress to the channel formation region 31 by the epitaxial growth film in addition to a compressive stress generated by a difference in thermal expansion coefficient between the insulating film 12 and the semiconductor substrate 11, and thus the carrier mobility of the channel formation region 31 can be more effectively improved.

Note that the present technology can also have the configuration below.

(1)

A semiconductor device comprising:

an insulating film that separates an n-type transistor formation region and a p-type transistor formation region from each other, wherein

each of the n-type transistor formation region and the p-type transistor formation region includes

a gate electrode formed in a first direction on a semiconductor substrate, and

source/drain regions formed on both sides of the gate electrode in a second direction different from the first direction, and

a distance from an interface between the insulating film and the source/drain regions to an end of the gate electrode in the second direction is different between the n-type transistor formation region and the p-type transistor formation region.

(2)

The semiconductor device according to (1), wherein the insulating film applies compressive stress or tensile stress to a channel formation region formed under the gate electrode in the second direction.

(3)

The semiconductor device according to (1) or (2), wherein when the insulating film applies the compressive stress to the channel formation region, the distance from the interface between the insulating film and the source/drain regions to the end of the gate electrode is shorter in the p-type transistor formation region than in the n-type transistor formation region.

(4)

The semiconductor device according to any one of (1) to (3), wherein when the insulating film applies the tensile stress to the channel formation region, the distance from the interface between the insulating film and the source/drain regions to the end of the gate electrode is shorter in the n-type transistor formation region than in the p-type transistor formation region.

(5)

The semiconductor device according to any one of (1) to (4), wherein the distance from the interface between the insulating film and the source/drain regions to the end of the gate electrode is at least partially different between the n-type transistor formation region and the p-type transistor formation region.

(6)

The semiconductor device according to any one of (1) to (5), wherein a part of the insulating film protrudes with respect to the source/drain regions.

(7)

The semiconductor device according to any one of (1) to (6), wherein a part of the insulating film protrudes with respect to any one of the source/drain regions.

(8)

The semiconductor device according to any one of (1) to (7), wherein a part of the source/drain regions protrudes with respect to the insulating film.

(9)

The semiconductor device according to any one of (1) to (8), wherein a part of any one of the source/drain regions protrudes with respect to the insulating film.

(10)

The semiconductor device according to any one of (2) to (4), wherein the insulating film under the gate electrode protrudes with respect to the channel formation region in the first direction.

(11)

The semiconductor device according to any one of (2) to (4), wherein the channel formation region protrudes with respect to the insulating film under the gate electrode in the first direction.

(12)

The semiconductor device according to any one of (3) to (11), wherein the source/drain regions of the p-type transistor formation region apply the compressive stress in the second direction to the channel formation region.

(13)

The semiconductor device according to any one of (1) to (12), wherein the source/drain regions of the n-type transistor formation region apply the tensile stress in the second direction to the channel formation region.

(14)

The semiconductor device according to any one of (1) to (13), comprising: on both sides of the gate electrode of the p-type transistor formation region, a stress application film that applies the compressive stress in the second direction to the channel formation region.

(15)

The semiconductor device according to any one of (1) to (13), including: on both sides of the gate electrode of the n-type transistor formation region, a stress application film that applies the tensile stress in the second direction to the channel formation region.

(16)

The semiconductor device according to any one of (1) to (15), wherein the insulating film is an element isolation region.

(17) A method for manufacturing a semiconductor device, comprising:

forming a resist pattern on a semiconductor substrate;

forming a groove in the semiconductor substrate using the resist pattern as a mask;

forming an insulating film in the groove;

forming a gate electrode on the semiconductor substrate in a first direction; and

forming source/drain regions on both sides of the gate electrode in a second direction different from the first direction, wherein

the resist pattern is formed in a manner that a distance from an interface between the insulating film and the source/drain regions to an end of the gate electrode in the second direction is different between an n-type transistor formation region and a p-type transistor formation region.

### REFERENCE SIGNS LIST

1, 2 SEMICONDUCTOR DEVICE
11, 111 SEMICONDUCTOR SUBSTRATE
12, 116 INSULATING FILM
13, 113 GATE ELECTRODE
14, 114 GATE INSULATING FILM
15, 115 SIDEWALL INSULATING FILM
21, 31, 121, 131 CHANNEL FORMATION REGION
22, 32, 122, 132 SOURCE/DRAIN REGION
23, 33, 123, 133 CONTACT ELECTRODE
24, 34 STRESS APPLICATION FILM
41 SILICON OXIDE FILM
42 SILICON NITRIDE FILM
43, 44 RESIST PATTERN
61, 92 GROOVE
81 DUMMY GATE STRUCTURE
91 INSULATING FILM
112 ELEMENT ISOLATION FILM
Tr1, Tr3 n-TYPE TRANSISTOR FORMATION REGION
Tr2, Tr4 p-TYPE TRANSISTOR FORMATION REGION

1. A semiconductor device comprising:
an insulating film that separates an n-type transistor formation region and a p-type transistor formation region from each other, wherein
each of the n-type transistor formation region and the p-type transistor formation region includes
a gate electrode formed in a first direction on a semiconductor substrate, and
source/drain regions formed on both sides of the gate electrode in a second direction different from the first direction, and
a distance from an interface between the insulating film and the source/drain regions to an end of the gate electrode in the second direction is different between the n-type transistor formation region and the p-type transistor formation region.

2. The semiconductor device according to claim 1, wherein the insulating film applies compressive stress or tensile stress to a channel formation region formed under the gate electrode in the second direction.

3. The semiconductor device according to claim 2, wherein when the insulating film applies the compressive stress to the channel formation region, the distance from the interface between the insulating film and the source/drain regions to the end of the gate electrode is shorter in the p-type transistor formation region than in the n-type transistor formation region.

4. The semiconductor device according to claim 2, wherein when the insulating film applies the tensile stress to the channel formation region, the distance from the interface between the insulating film and the source/drain regions to the end of the gate electrode is shorter in the n-type transistor formation region than in the p-type transistor formation region.

5. The semiconductor device according to claim 1, wherein the distance from the interface between the insulating film and the source/drain regions to the end of the gate electrode is at least partially different between the n-type transistor formation region and the p-type transistor formation region.

6. The semiconductor device according to claim 1, wherein a part of the insulating film protrudes with respect to the source/drain regions.

7. The semiconductor device according to claim 6, wherein a part of the insulating film protrudes with respect to any one of the source/drain regions.

8. The semiconductor device according to claim 1, wherein a part of the source/drain regions protrudes with respect to the insulating film.

9. The semiconductor device according to claim 8, wherein a part of any one of the source/drain regions protrudes with respect to the insulating film.

10. The semiconductor device according to claim 2, wherein the insulating film under the gate electrode protrudes with respect to the channel formation region in the first direction.

11. The semiconductor device according to claim 2, wherein the channel formation region protrudes with respect to the insulating film under the gate electrode in the first direction.

12. The semiconductor device according to claim 3, wherein the source/drain regions of the p-type transistor formation region apply the compressive stress in the second direction to the channel formation region.

13. The semiconductor device according to claim 4, wherein the source/drain regions of the n-type transistor formation region apply the tensile stress in the second direction to the channel formation region.

14. The semiconductor device according to claim 3, comprising: on both sides of the gate electrode of the p-type transistor formation region, a stress application film that applies the compressive stress in the second direction to the channel formation region.

15. The semiconductor device according to claim 4, comprising: on both sides of the gate electrode of the n-type transistor formation region, a stress application film that applies the tensile stress in the second direction to the channel formation region.

16. The semiconductor device according to claim 1, wherein the insulating film is an element isolation region.

17. A method for manufacturing a semiconductor device, comprising:
forming a resist pattern on a semiconductor substrate;
forming a groove in the semiconductor substrate using the resist pattern as a mask;
forming an insulating film in the groove;
forming a gate electrode on the semiconductor substrate in a first direction; and
forming source/drain regions on both sides of the gate electrode in a second direction different from the first direction, wherein
the resist pattern is formed in a manner that a distance from an interface between the insulating film and the source/drain regions to an end of the gate electrode in the second direction is different between an n-type transistor formation region and a p-type transistor formation region.
